(19) United States
(12) Patent Application Publication
(10) Pub. No.: US 2018/0019141 A1
(43) Pub. Date: Jan. 18, 2018

(54) LASER SYSTEM AND LASER ANNEALING APPARATUS

(71) Applicants: Kyushu University, Fukuoka (JP); Gigaphoton Inc., Tochigi (JP)

(72) Inventors: Tomoyuki OHKUBO, Fukuoka-shi (JP); Hiroshi IKENOUE, Fukuoka-shi (JP); Kouji KAKIZAKI, Oyama-shi (JP); Yasuhiro KAMBA, Oyama-shi (JP); Osamu WAKABAYASHI, Oyama-shi (JP)

(73) Assignees: Kyushu University, Fukuoka (JP); Gigaphoton Inc., Tochigi (JP)

(21) Appl. No.: 15/678,950

(22) Filed: Aug. 16, 2017

Related U.S. Application Data
(63) Continuation of application No. PCT/JP2015/057779, filed on Mar. 16, 2015.

(51) Int. Cl. H01L 21/67

(52) U.S. Cl. CPC H01L 21/67115; H01L 21/67276

(57) ABSTRACT

A laser system may serve as a light source of a laser annealing apparatus that irradiates a workpiece with a pulse laser beam. The laser system may include: a laser apparatus configured to generate the pulse laser beam; a time-domain pulse waveform changing apparatus configured to change time-domain pulse waveform of the pulse laser beam; and a controller configured to receive at least one parameter for generating the time-domain pulse waveform from the laser annealing apparatus and to control the time-domain pulse waveform changing apparatus.

### TECHNICAL FIELD

The present disclosure relates to a laser system and laser annealing apparatus.

### BACKGROUND ART

Thin-film transistors (TFTs) are used as driving elements in a flat panel display using a glass substrate. To achieve a high-resolution display, it is necessary to produce TFTs each having a high driving force. Polycrystalline silicon, indium gallium zinc oxide (IGZO), or the like is used for a semiconductor thin-film as a channel material of the TFTs. The polycrystalline silicon or the IGZO has higher carrier mobility and achieves better on/off properties of transistors than amorphous silicon.

The semiconductor thin film is also expected to be applied to 3D-ICs for providing devices having higher functionalities. The 3D-ICs can be achieved by forming active elements such as sensors, amplifier circuits, or CMOS circuits on the uppermost layer of an integrated circuit. To this end, there is a demand for a technology that produces a semiconductor thin-film having higher quality.

Further, with increases in the variety of information terminal devices, there has grown a demand for flexible displays or flexible computers that are small and lightweight, consume less power, and can be folded freely. Meeting such a demand requires establishing a technology that forms a high-quality semiconductor thin-film on a plastic substrate such as polyethylene terephthalate (PET).

To form a high-quality semiconductor thin-film on the glass substrate, the integrated circuit, or the plastic substrate, it is necessary to crystallize the semiconductor thin-film without thermal damage to such substrates. The glass substrate used in a display requires a process temperature of 400° C. or less; the integrated circuit requires a process temperature of 400° C. or less; and the PET serving as the plastic substrate requires a process temperature of 200° C. or less.

Laser annealing is used as a technology that crystallizes a semiconductor thin-film without thermal damage to the ground substrate thereof. This method uses an ultraviolet pulse laser beam to be absorbed by an upper-layer semiconductor thin-film in order to suppress the damage to the substrate caused by thermal diffusion.

If the semiconductor thin-film is silicon, an XeF excimer laser having a wavelength of 351 nm, an XeCl excimer laser having a wavelength of 308 nm, a KrF excimer laser having a wavelength of 248 nm, or the like is used. These ultraviolet-range gas lasers have advantages in that, compared to solid-state lasers, they have low laser-beam coherence and excellent energy uniformity on a laser-beam irradiated surface and can uniformly anneal a wide area with high pulse energy.

Patent Document 1: Japanese Patent Application. Publication No. H10-012950

Patent Document 2: US Patent Application Publication No. 2012/0260847

Patent Document 3: International Publication No. WO 2014/156818

Patent Document 4: Japanese Patent No. 4373115

Patent Document 5: Japanese Patent Application Publication No. 2008-211136

Patent Document 6: U.S. Pat. No. 8,737,438

### SUMMARY

A laser system of one aspect of the present disclosure may be a laser system serving as a light source of a laser annealing apparatus that irradiates a workpiece with a pulse laser beam. The laser system may include a laser apparatus configured to generate the pulse laser beam, a time-domain pulse waveform changing apparatus configured to change time-domain pulse waveform of the pulse laser beam, and a controller configured to receive at least one parameter for generating the time-domain pulse waveform from the laser annealing apparatus and to control the time-domain pulse waveform changing apparatus.

A laser annealing apparatus of another aspect of the present disclosure may be a laser annealing apparatus for irradiating a workpiece with a pulse laser beam. The laser annealing apparatus may include a laser apparatus configured to generate the pulse laser beam, a time-domain pulse waveform changing apparatus configured to change time-domain pulse waveform of the pulse laser beam, optics configured to irradiate the workpiece with the pulse laser beam, a fluence changing unit configured to change fluence of the pulse laser beam on the workpiece, and a controller configured to control the time-domain pulse waveform changing apparatus and the fluence changing unit based on an irradiation parameter set including at least one parameter for generating the time-domain pulse waveform and a target value of the fluence of the pulse laser beam on the workpiece.

### BRIEF DESCRIPTION OF DRAWINGS

Exemplary embodiments of the present disclosure will be described below with reference to the appended drawings.

FIG. 1 schematically shows a configuration of a laser annealing apparatus of a comparative example;

FIG. 2 shows a detailed configuration of a laser apparatus shown in FIG. 1;

FIG. 3 shows an internal configuration of a laser chamber shown in FIG. 2 and a configuration of a pulse power module shown in FIG. 2;

FIG. 4 is a graph showing an example of a time-domain pulse waveform of a pulse laser beam outputted from the laser apparatus;

FIG. 5 schematically shows a configuration of a laser annealing apparatus of a first embodiment of the present disclosure;

FIG. 6A shows a configuration of an optical pulse stretcher shown in FIG. 5;

FIG. 6B shows the optical pulse stretcher in which a beam splitter has been moved to a position different from that in FIG. 6A and in which postures of concave mirrors are different from those in FIG. 6A;

FIG. 6C shows the optical pulse stretcher in which postures of the concave mirrors are different from those in FIG. 6B;

FIG. 6D shows the beam splitter, a holder, an arm, a moving table, and a uniaxial stage as viewed in a direction perpendicular to the reflection surface of the beam splitter;

FIG. 6E shows the beam splitter, the holder, the arm, the moving table, and the uniaxial stage in which the beam splitter has been moved to a position different from that in FIG. 6D;

FIG. 7 is a flowchart showing a process to set a time-domain pulse waveform performed by an annealing controller shown in FIG. 5;

FIG. 8A is a flowchart showing details of a process shown in FIG. 7 to calculate a pulse width with the lowest reflectance of the beam splitter;

FIG. 8B shows an example of the time-domain pulse waveform of the pulse laser beam outputted from the optical pulse stretcher with the lowest reflectance of the beam splitter;

FIG. 9A is a flowchart showing details of a process shown in FIG. 7 to generate irradiation parameter sets;

FIG. 9B shows an example of a data structure where the irradiation parameter sets are stored in a table format;

FIG. 10 is a flowchart showing details of a process shown in FIG. 7 to set an irradiation parameter set for a laser system;

FIG. 11A is a flowchart showing details of a process shown in FIG. 7 to calculate pulse parameters;

FIG. 11B shows an example of the time-domain pulse waveform of the pulse laser beam outputted from the optical pulse stretcher;

FIG. 12A is a flowchart showing details of a process shown in FIG. 7 to measure a duration of a melted state and a status of crystallization;

FIG. 12B shows an example of a temporal change in the reflectance of the irradiated region of a workpiece reflecting the pulse laser beam;

FIG. 13 is a flowchart showing details of a process shown in FIG. 7 to select an optimum irradiation parameter set;

FIG. 14 is a graph showing a relationship between fluence of the pulse laser beam with which the workpiece is irradiated and the size of each crystal grain formed in the workpiece, and a relationship between the fluence of the pulse laser beam with which the workpiece is irradiated and the duration of the melted state;

FIG. 15 is a graph showing an example of a preferable time-domain pulse waveform;

FIG. 16A shows a configuration of an optical pulse stretcher used in a laser annealing apparatus of a second embodiment of the present disclosure;

FIG. 16B shows a plurality of beam splitters used in the optical pulse stretcher shown in FIG. 16A as viewed in a direction perpendicular to the reflection surfaces of the beam splitters;

FIG. 17A is a flowchart showing details of a process to select an optimum irradiation parameter set performed by a laser annealing apparatus of a third embodiment of the present disclosure;

FIG. 17B shows an example of a relationship between the duration of the melted state and the fluence;

FIG. 18 schematically shows a configuration of a laser annealing apparatus of a fourth embodiment of the present disclosure;

FIG. 19 is a flowchart showing a process to set a time-domain pulse waveform performed by an annealing controller shown in FIG. 18;

FIG. 20 is a flowchart showing details of a process shown in FIG. 19 to calculate a pulse width of a pulse laser beam outputted from a single laser unit;

FIG. 21A is a flowchart showing details of a process shown in FIG. 19 to generate irradiation parameter sets;

FIG. 21B shows an example of the time-domain pulse waveform of the pulse laser beam outputted from the laser system;

FIG. 21C shows an example of a data structure where the irradiation parameter sets are stored in a table format;

FIG. 22 is a flowchart showing a process to set an irradiation parameter set in a fifth embodiment of the present disclosure;

FIG. 23A is a flowchart showing a first example of a process shown in FIG. 22 to receive the irradiation parameter set;

FIG. 23B is a flowchart showing a second example of the process shown in FIG. 22 to receive the irradiation parameter set;

FIG. 24A is a flowchart showing a first example of a process shown in FIG. 22 to set the received irradiation parameter set;

FIG. 24B is a flowchart showing a second example of the process shown in FIG. 22 to set the received irradiation parameter set; and

FIG. 25 is a block diagram schematically showing a configuration of a controller.

### DESCRIPTION OF EMBODIMENTS

### Contents

1. Outline

2. Laser Annealing Apparatus of Comparative Example
2.1 Configuration of Laser Annealing Apparatus
2.2 Operation of Laser Annealing Apparatus
2.3 Details of Laser Apparatus
2.4 Problems

3. Laser Annealing Apparatus including Optical Pulse Stretcher (First Embodiment)
3.1 Configuration
3.2 Operation
3.3 Configuration of Optical Pulse Stretcher
3.4 Operation of Optical. Pulse Stretcher
3.5 Process by Annealing Controller
   3.5.1 Main Flow
   3.5.2 Details of S100
   3.5.3 Details of S110
   3.5.4 Details of S130
   3.5.5 Details of S150
   3.5.6 Details of S160
   3.5.7 Details of S200
3.6 Selecting Irradiation Condition

4. Variation of Beam Splitter (Second Embodiment)

5. Variation of Selecting Irradiation Condition (Third Embodiment)

6. Laser Annealing Apparatus Including Plurality of Laser Units (Fourth Embodiment)
6.1 Configuration and Operation
6.2 Process by Annealing Controller
   6.2.1 Main Flow
   6.2.2 Details of S100b
   6.2.3 Details of S110b
6.3 Effect

7. Example where Irradiation Parameter Set is Provided from External Apparatus (Fifth Embodiment)
7.1 Main Flow
7.2 Details of S320 (First Example)
7.3 Details of S320 (Second Example)
7.4 Details of S330 (First Example)
7.5 Details of S330 (Second Example)

8. configuration of Controller

Now, embodiments of the present disclosure will be described in detail with reference to the drawings. The embodiments described below are intended to be illustrative of the present disclosure and not to limit the content thereof. Not all the configurations and operations described in the embodiments are essential to the present disclosure. Identical reference symbols are assigned to identical elements and redundant descriptions are omitted.

### 1. Outline

Properties of polycrystals formed using a pulse laser beam outputted from a laser annealing apparatus may vary with the time-domain pulse waveform of the pulse laser beam. A conventional laser annealing apparatus may have difficulty in optimizing the time-domain pulse waveform of the pulse laser beam.

The present disclosure relates to a laser annealing apparatus that changes the time-domain pulse waveform of a pulse laser beam outputted from a laser system serving as the light source of the laser annealing apparatus.

### 2. Laser Annealing Apparatus of Comparative Example

### 2.1 Configuration of Laser Annealing Apparatus

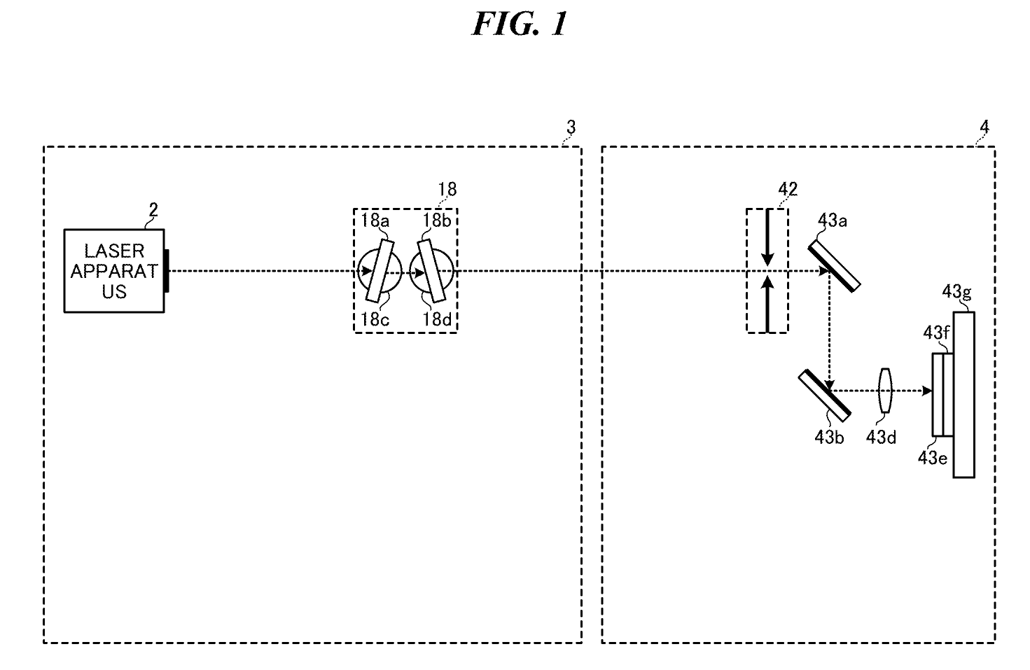

FIG. 1 schematically shows a configuration of a laser annealing apparatus of a comparative example. The laser annealing apparatus may include a laser system 3 and an annealing apparatus 4.

The laser system 3 may include a laser apparatus 2 and an attenuator 18. The laser apparatus 2 may use one of ArF, KrF, XeCl, and XeF as a laser medium. The attenuator 18 may be disposed in an optical path of a pulse laser beam outputted from the laser apparatus 2. The attenuator 18 may include two partial reflection mirrors 18a and 18b, and rotating stages 18c and 18d for the respective partial reflection mirrors. The two partial reflection mirrors 18a and 18b may be optical elements whose transmittances vary with incident angles of the pulse laser beam.

The annealing apparatus 4 may include a slit 42, high-reflective mirrors 43a and 43b, transfer optics 43d, a table 43f, and an XYZ stage 43g. The slit 42 may be disposed in the optical path of the pulse laser beam passed through the attenuator 18. The slit 42 may be disposed such that a region having a uniform optical intensity distribution of a cross-section of the pulse laser beam passes through the slit 42.

The high-reflective mirrors 43a and 43b may be disposed such that the pulse laser beam passed through the slit 42 enters the transfer optics 43d. The transfer optics 43d may include one or more convex lenses or may include one or more convex lenses and one or more concave lenses.

The table 43f may support a workpiece 43e. The workpiece 43e may be a glass substrate on which an amorphous silicon thin-film is formed. The XYZ stage 43g may support the table 43f. The XYZ stage 43g may be adjusted so that a transfer image of the slit 42 is formed on the workpiece 43e on the table 43f.

### 2.2 Operation of Laser Annealing Apparatus

Postures of the two partial reflection mirrors 18a and 18b may be controlled using the rotating stages 18c and 18d so that the incident angles of the pulse laser beam become approximately equal to each other and so that their transmittances each becomes a desired transmittance. Thus, the pulse laser beam outputted from the laser apparatus 2 may be attenuated into a pulse laser beam having desired pulse energy and may pass through the attenuator 18.

The pulse laser beam passed through the attenuator 18 may pass through the slit 42, then be reflected by the high-reflective mirrors 43a and 43b, and then be incident on the transfer optics 43d. The transfer optics 43d may form a transfer image of the slit 42 on the workpiece 43e. The workpiece 43e may thus be irradiated with the pulse laser beam and the amorphous silicon in the irradiated region may melt. After the irradiation of the pulse laser beam is ended, the melted amorphous silicon may crystallize.

### 2.3 Details of Laser Apparatus

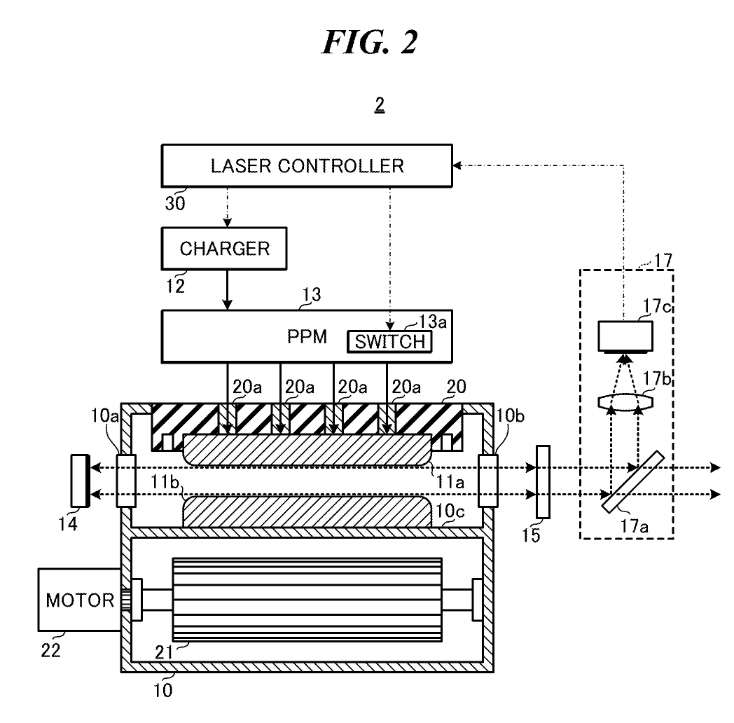

FIG. 2 shows a detailed configuration of the laser apparatus shown in FIG. 1. As shown in FIG. 2, the laser apparatus 2 may include a laser chamber 10, a pair of electrodes 11a and 11b, a charger 12, and a pulse power module (PPM) 13. FIG. 2 shows an internal configuration of the laser chamber 10 as viewed in a direction approximately perpendicular to the traveling direction of the laser beam.

The laser apparatus 2 may also include a cross-flow fan 21 and a motor 22. The laser apparatus 2 may further include a high-reflective mirror 14, an output coupling mirror 15, a pulse energy measuring unit 17, and a laser controller 30,

The laser chamber 10 may be a chamber in which the above-described laser medium is sealed. The pair of electrodes 11a and 11b may be disposed in the laser chamber 10 as electrodes for exciting the laser medium by electric discharge. The laser chamber 10 may have an opening sealed by an insulating member 20. The electrode 11a may be supported by the insulating member 20, and the electrode 11b may be supported by an internal partition plate 10c of the laser chamber 10. Conductive elements 20a may be embedded in the insulating member 20. The conductive elements 20a may electrically connect high-voltage terminals of the pulse power module 13 and the electrode 11a so that a high voltage from the pulse power module 13 is applied to the electrode 11a.

The rotary shaft of the cross-flow fan 21 may be connected to the motor 22 disposed on the outside of the laser chamber 10. When the motor 22 rotates the cross-flow fan 21, laser gas in the laser chamber 10 may be circulated.

The charger 12 may include, for example, a capacitor connected to a power supply. The charger 12 may hold electric energy for applying the high voltage between the pair of electrodes 11a and 11b. The pulse power module 13 may include a switch 13a controlled by the laser controller 30. When the switch 13a is turned on, the pulse power module 13 may generate a pulsed high voltage from the electric energy in the charger 12 and apply the high voltage between the pair of electrodes 11a and 11b.

The application of the high voltage between the pair of electrodes 11a and 11b may cause electric discharge therebetween. The energy of the electric discharge may excite the laser medium in the laser chamber 10 to cause the laser medium to shift to a high energy level. The laser medium may then shift back to a low energy level, generating light having a wavelength according to the difference in the energy levels.

The laser chamber 10 may be provided with windows 10a and 10b at both ends thereof. The light generated in the laser chamber 10 may be emitted through the windows 10a and 10b.

The light emitted from the window 10a of the laser chamber 10 may be reflected by the high-reflective mirror 14 with a high reflectance to be returned into the laser chamber 10.

The output coupling mirror 15 may be coated with a partial reflection film, A part of the light emitted from the window 10b of the laser chamber 10 may be transmitted by the output coupling mirror 15 to be outputted. Another part of the light may be reflected to be returned into the laser chamber 10.

The high-reflective mirror 14 and the output coupling mirror 15 may constitute an optical resonator. The light emitted from the laser chamber 10 may travel back and forth between the high-reflective mirror 14 and the output coupling mirror 15. The light may be amplified each time it passes through the laser gain region between the electrodes 11a and 11b. A part of the amplified light may be outputted as a pulse laser beam through the output coupling mirror 15.

The pulse energy measuring unit 17 may include a beam splitter 17a, focusing optics 17b, and an optical sensor 17c. A part of the pulse laser beam transmitted by the output coupling mirror 15 may be transmitted by the beam splitter 17a at a high transmittance. Another part of the pulse laser beam may be reflected by the beam splitter 17a to the focusing optics 17b. The light reflected by the beam splitter 17a may be focused by the focusing optics 17b on the photosensitive surface of the optical sensor 17c. The optical sensor 17c may detect the pulse energy of the laser beam focused on the photosensitive surface and output data on the detected pulse energy to the laser controller 30.

The laser controller 30 may send a charging voltage setting signal to the charger 12 or may send an emitting trigger signal to the switch 13a of the pulse power module 13.

The laser controller 30 may receive the data on the detected pulse energy from the pulse energy measuring unit 17. The laser controller 30 may control the charging voltage of the charger 12 with reference to the data on the detected pulse energy to control the energy of the pulse laser beam. The laser controller 30 may also count the number of oscillation pulses of the laser apparatus 2 based on the data received from the pulse energy measuring unit 17.

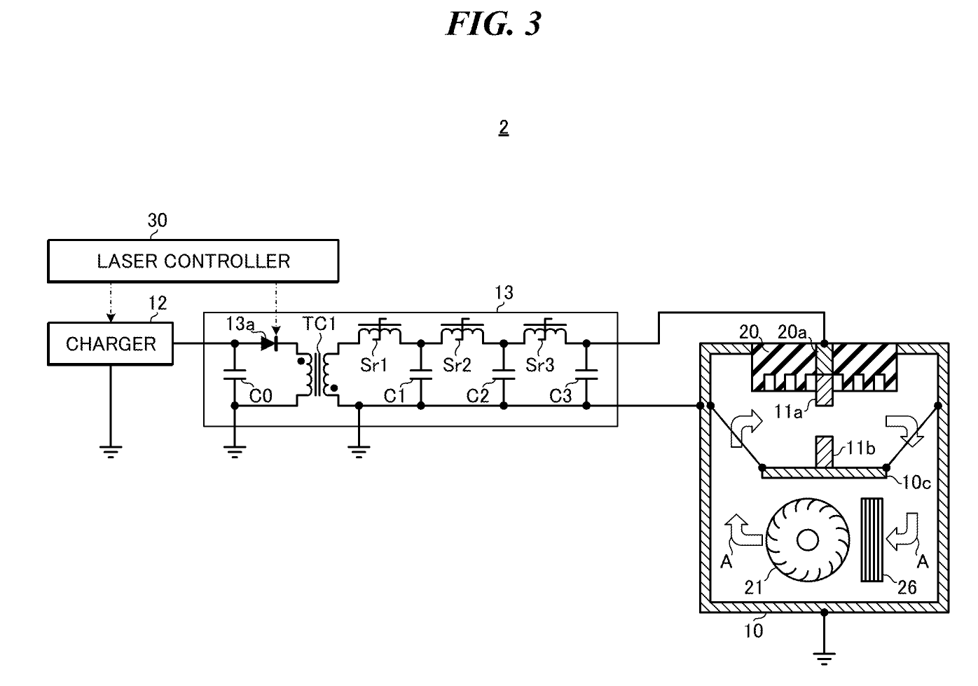

FIG. 3 shows an internal configuration of the laser chamber shown in FIG. 2 and a configuration of the pulse power module shown in. FIG. 2. FIG. 3 shows an internal configuration of the laser chamber 10 as viewed in a direction approximately parallel to the traveling direction of a laser beam. A conductive member of the laser chamber 10 including the internal partition plate 10c may be connected to the ground potential. The electrode 11b may be connected to the ground potential through the internal partition plate 10c.

The laser chamber 10 may contain the pair of electrodes 11a and 11b, the cross-flow fan 21, and a heat exchanger 26. The cross-flow fan 21 may rotate such that the laser gas may be circulated in the laser chamber 10 as shown by arrows A. When the laser gas is heated by the electric discharge, the heat exchanger 26 may exhaust the heat energy of the laser gas out of the laser chamber 10.

The pulse power module 13 may include a charging capacitor C0, the switch 13a, a boosting transformer TC1, magnetic switches Sr1 to Sr3, and capacitors C1 to C3.

The magnetic switches Sr1 to Sr3 may each include a saturable reactor. Each of the magnetic switches Sr1 to Sr3 may be switched to a low impedance state when the time integral of the voltage applied across the magnetic switch becomes a predetermined threshold determined by the properties of the magnetic switch.

The laser controller 30 may set a charging voltage of the charger 12. The charger 12 may charge the charging capacitor C0 in accordance with the set charging voltage.

The switch 13a of the pulse power module 13 may receive the emitting trigger signal from the laser controller 30. Upon receiving the emitting trigger signal, the switch 13a may be turned on. When the switch 13a is turned on, electric current may flow from the charging capacitor C0 to the primary side of the boosting transformer TC1.

The electric current through the primary side of the boosting transformer TC1 may cause electromagnetic induction to generate reverse electric current through the secondary side of the boosting transformer TC1. The reverse electric current through the secondary side of the boosting transformer TC1 may allow the time integral of the voltage across the magnetic switch Sr1 to reach the threshold.

When the time integral of the voltage across the magnetic switch Sr1 reaches the threshold, the magnetic switch Sr1. may be magnetically saturated and closed.

When the magnetic switch Sr1 is closed, electric current may flow from the secondary side of the boosting transformer TC1 to the capacitor C1 to charge the capacitor C1.

Charging the capacitor C1 may allow the magnetic switch Sr2 to be magnetically saturated and closed.

When the magnetic switch Sr2 is closed, electric current may flow from the capacitor C1 to the capacitor C2 to charge the capacitor C2. The electric current to charge the capacitor C2 may have a shorter pulse width than the electric current to charge the capacitor C1.

Charging the capacitor C2 may allow the magnetic switch Sr3 to be magnetically saturated and closed.

When the magnetic switch Sr3 is closed, electric current may flow from the capacitor C2 to the capacitor C3 to charge the capacitor C3. The electric current to charge the capacitor C3 may have a shorter pulse width than the electric current to charge the capacitor C2.

As seen above, the electric current may sequentially flow from the capacitor C1 to the capacitor C2 and then from the capacitor C2 to the capacitor C3. The pulse width of the electric current may thus be shrunk, and the voltage may be increased.

When the voltage across the capacitor C3 reaches a breakdown voltage of the laser gas, the laser gas may be dielectrically broken down between the pair of electrodes 11a and 11b. Thus, the laser gas may be excited, causing laser oscillation, and the pulse laser beam may be outputted. Since the above-described discharge operation is repeated with the switching operation of the switch 13a, the pulse laser beam may be emitted at a predetermined oscillation frequency.

### 2.4 Problems

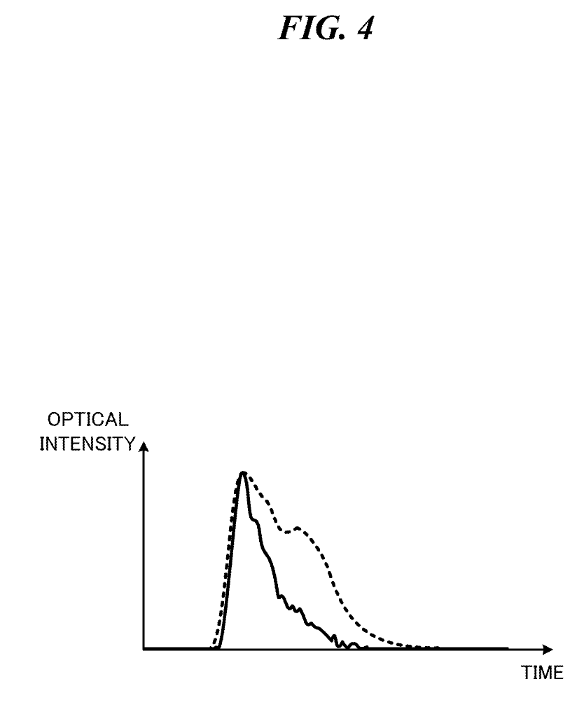

FIG. 4 is a graph showing an example of the time-domain pulse waveform of the pulse laser beam outputted from the laser apparatus. In FIG. 4, a broken line shows a time-domain pulse waveform of the pulse laser beam when a ratio K=C_{P}/C_{P-1} of the capacitance C_{P} of the capacitor C3 to the capacitance C_{P-1} of the capacitor C2 is 0.7, and a solid line shows a time-domain pulse waveform of the pulse laser beam when the ratio K is 0.95.

If the ratio K is smaller than 1, amount of energy charged to the capacitor C3 may be smaller than that charged to the capacitor C2 and thus surplus energy may remain. After the energy charged to the capacitor C3 causes the electric discharge between the electrodes 11a and 11b, the surplus energy may cause an inverted current and cause another electric discharge. Thus, the pulse width of the pulse laser beam may be stretched.

Japanese Patent Application Publication No. H10-012950 discloses that a pulse width suitable for annealing is achieved by the pulse stretch resulting from the electric discharge due to the inverted current. However, the time-domain pulse waveform may vary every pulse due to a change in condition of the laser gas or condition of the electric discharge. A variation in the time-domain pulse waveform may change properties of polycrystals formed by annealing.

US Patent Application Publication No. 2012/0260847 and U.S. Pat. No. 8,737,438 disclose that the pulse width is increased using an optical pulse stretcher. However, it may be difficult to optimize the time-domain pulse waveform by simply using an optical pulse stretcher.

In order to solve the problem, in embodiments described below, a beam splitter included in an optical pulse stretcher may be changed in its reflectance. Also, a delay optical path of delay optics included in the optical pulse stretcher may be changed in its optical path length. The ratio K=C_{P}/C_{P-1} of the capacitance C_{P} of the capacitor C3 to the capacitance C_{P-1} of the capacitor C2 of the pulse power module 13 may be in the following ranges:

Preferably, 0.85≦K≦1.15; and

More preferably, 0.9≦K≦1.05.

By setting the ratio K to a value close to 1, it is possible to reduce the surplus energy and to suppress the inverted current. As a result, it may be possible to generate stable electric discharge and thus to stabilize the time-domain pulse waveform of the outputted pulse laser beam.

### 3. Laser Annealing Apparatus Including Optical Pulse Stretcher (First Embodiment)

### 3.1 Configuration

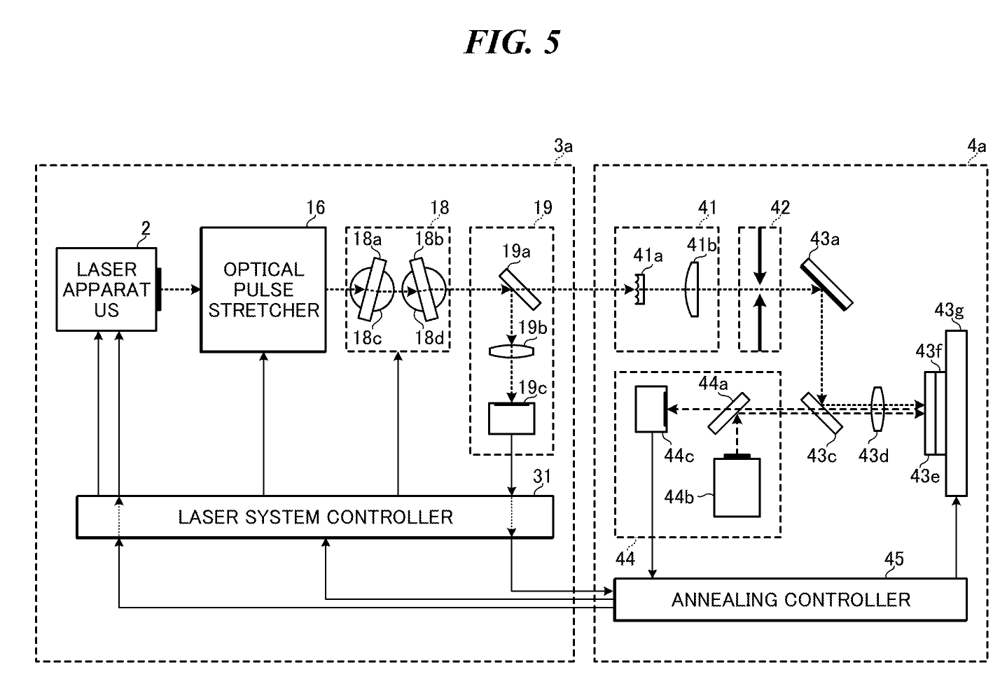

FIG. 5 schematically shows a configuration of a laser annealing apparatus of a first embodiment of the present disclosure. In the laser annealing apparatus of the first embodiment, a laser system 3a may include the elements of the laser system 3 described with reference to FIG. 1. The laser system 3a may also include an optical pulse stretcher 16, a time-domain pulse waveform measuring unit 19, and a laser system controller 31. Also, in the laser annealing apparatus of the first embodiment, an annealing apparatus 4a may include the eluents of the annealing apparatus 4 described with reference to FIG. 1. The annealing apparatus 4a may also include a beam homogenizer 41, a melting state measuring unit 44, and an annealing controller 45. The annealing apparatus 4a may also include a high-reflective mirror 43c in place of the high-reflective mirror 43b.

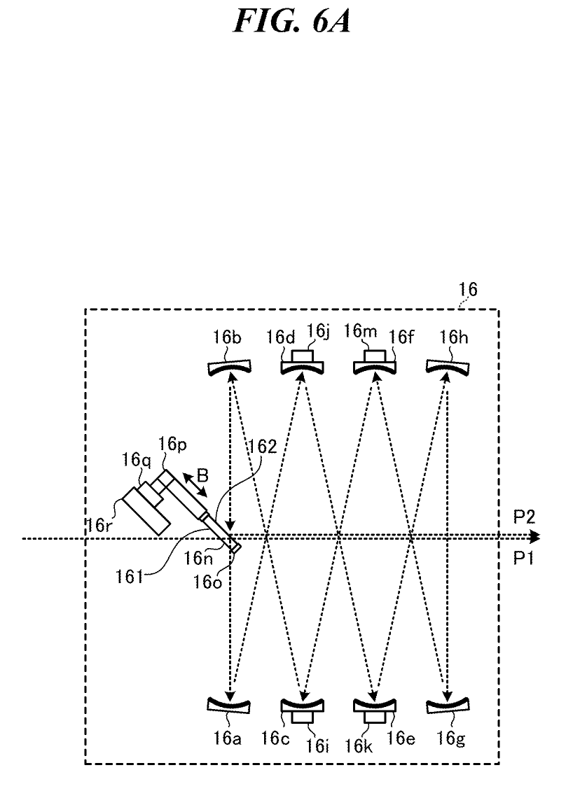

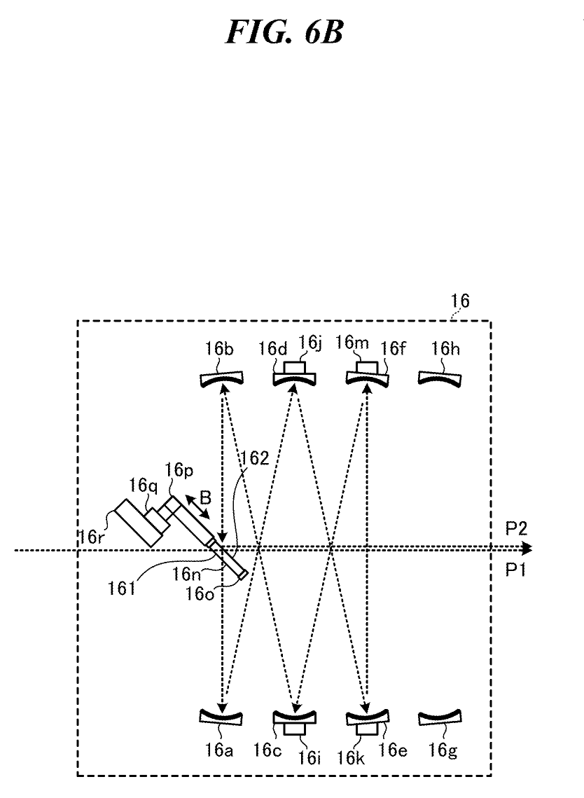

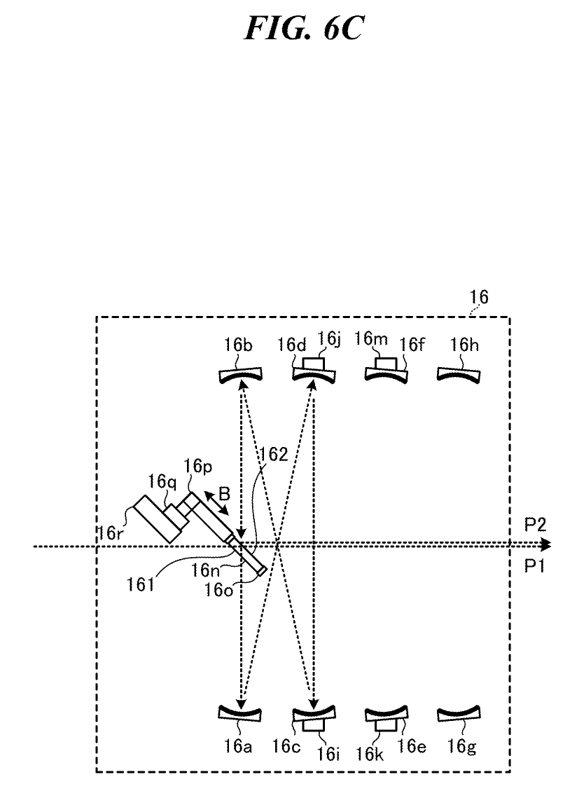

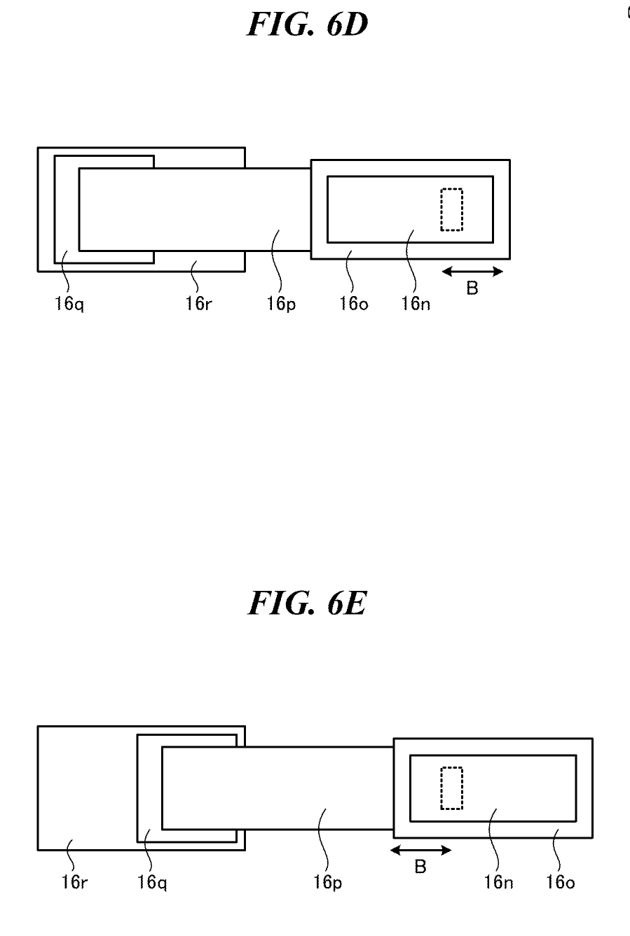

The optical pulse stretcher 16 may be disposed in the optical path of the pulse laser beam between the laser apparatus 2 and the attenuator 18. The optical pulse stretcher 16 may include a beam splitter and delay optics. Details of the optical pulse stretcher 16 will be described later with reference to FIGS. 6A to 6E.

The time-domain pulse waveform measuring unit 19 may be disposed in the optical path of the pulse laser beam between the attenuator 18 and the annealing apparatus 4a. The time-domain pulse waveform measuring unit 19 may include a beam splitter 19a, focusing optics 19b, and an optical sensor 19c. The beam splitter 19a may transmit a part of the pulse laser beam from the attenuator 18 at a high transmittance. The beam splitter 19a may reflect another part of the pulse laser beam toward the focusing optics 19b. The focusing optics 19b may focus the light reflected by the beam splitter 19a on the photosensitive surface of the optical sensor 19c. The optical sensor 19c may be a high-speed photodiode or a biplanar tube.

The beam homogenizer 41 may be disposed in the optical path of the pulse laser beam between the time-domain pulse waveform measuring unit 19 and the slit 42. The beam homogenizer 41 may include a fly-eye lens 41a and condenser optics 41b. The condenser optics 41b may be disposed such that the rear-side focal point thereof approximately coincides with the position of the slit 42. The fly-eye lens 41a may be disposed such that the position of the focal plane including the front-side focal points of multiple lenses included in the fly-eye lens 41a and the position of the front-side focal plane of the condenser optics 41b approximately coincide with each other.

The high-reflective mirror 43c may be a dichroic mirror that reflects an ultraviolet-range pulse laser beam outputted from the laser apparatus 2 with a high reflectance and transmits visible light.

The melting state measuring unit 44 may include a beam splitter 44a, a semiconductor laser 44b, and an optical sensor 44c. The semiconductor laser 44b may output a laser beam in the visible light range. For example, the semiconductor laser 44b may be one that outputs a laser beam having a wavelength of 1 μm to 660 nm. The beam splitter 44a may be a half mirror that reflects a part of the laser beam and transmits another part thereof.

A part of the laser beam outputted from the semiconductor laser 44b may be reflected by the beam splitter 44a, transmitted through the high-reflective mirror 43c, and reflected by the workpiece 43e. The laser beam reflected by the workpiece 43e may be transmitted through the high-reflective mirror 43c and then transmitted through the beam splitter 44a. The optical sensor 44c may be disposed in the optical path of the laser beam transmitted through the high-reflective mirror 43c and then transmitted through the beam splitter 44a. The optical sensor 44c may be a photodiode that is sensitive to the wavelength of the laser beam outputted from the semiconductor laser 44b. Alternatively, a band-pass filter that selectively transmits the laser beam having the wavelength outputted from the semiconductor laser 44b may be disposed in the optical path of the laser beam between the high-reflective mirror 43c and the optical sensor 44c.

### 3.2 Operation

The annealing controller 45 may control the XYZ stage 43g so that the workpiece 43e is placed in a predetermined position. The annealing controller 45 may send data on a target pulse energy Et to the laser system controller 31 so that the fluence of the pulse laser beam on the workpiece 43e becomes a predetermined value. The target pulse energy Et may be one for the pulse laser beam passed through the attenuator 18.

The laser system controller 31 may send, to the laser apparatus 2, the target value EL1 of the pulse energy of the pulse laser beam outputted from the laser apparatus 2. Then, the laser system controller 31 may send a signal for controlling transmittance T2 of the attenuator 18 so that the target pulse energy Et of the pulse laser beam passed through the attenuator 18 becomes Et=T1·T2·EL1. Here, T1 may be a transmittance of the optical pulse stretcher 16.

The annealing controller 45 may send an emitting trigger signal through the laser system controller 31 to the laser apparatus 2. Upon receipt of the emitting trigger signal, the laser apparatus 2 may output the pulse laser beam having pulse energy equivalent to the target value EL1. The outputted pulse laser beam may enter the optical pulse stretcher 16 and be pulse-stretched.

The pulse-stretched pulse laser beam may be attenuated into a pulse laser beam having desired pulse energy by the attenuator 18. Then, a part of the pulse laser beam may be reflected by the beam splitter 19a of the time-domain pulse waveform measuring unit 19, pass through the focusing optics 19b, and enter the optical sensor 19c.

The laser system controller 31 may receive a signal from the optical sensor 19c and measure the time-domain pulse waveform of the pulse laser beam. The laser system controller 31 may also integrate the time-domain pulse waveform to calculate pulse energy and then determine whether the calculated pulse energy reaches the target pulse energy Et. The laser system controller 31 may send data on the measured time-domain pulse waveform to the annealing controller 45.

The pulse laser beam passed through the time-domain pulse waveform measuring unit 19 may enter the annealing apparatus 4a. With the pulse laser beam having entered the annealing apparatus 4a, the beam homogenizer 41 may perform Koehler-illumination on the slit 42. This may cause optical intensity distribution of the pulse laser beam to be uniform. The pulse laser beam passed through the slit 42 may be reflected by the high-reflective mirror 43a and then reflected by the high-reflective mirror 43c. The transfer optics 43d may transmit the pulse laser beam to form a transfer image of the slit 42 on the workpiece 43e. Thus, a part of the amorphous silicon in the workpiece 43e may melt and then crystallize.

The laser beam outputted from the semiconductor laser 44b of the melting state measuring unit 44 may be reflected by the beam splitter 44a, pass through the high-reflective mirror 43c and the transfer optics 43d, and be incident on an irradiation region of the workpiece 43e.

In the process in which the amorphous silicon in the workpiece 43e melts and then crystallizes, changes may occur in reflectance of the workpiece 43e reflecting the laser beam outputted from the semiconductor laser 44b. The annealing controller 45 may measure a temporal change in optical intensity of the reflected light of the laser beam outputted from the semiconductor laser 44b using the optical sensor 44c. The annealing controller 45 may then calculate a temporal change in the reflectance of the workpiece 43e. The reflectance of the workpiece 43e may be calculated using a reference value. The reference value may be an optical intensity of reflected light from a sample material having a high reflectance placed in the position of the workpiece 43e.

### 3.3 Configuration of Optical Pulse Stretcher

FIG. 6A shows a configuration of the optical pulse stretcher shown in FIG. 5. The optical pulse stretcher 16 may include a beam splitter 16n and concave mirrors 16a to 16h.

The beam splitter 16n may include a substrate that transmits the pulse laser beam at a high transmittance. A first surface 161 of this substrate may be coated with a reduced reflection film, and a second surface 162 thereof may be coated with a partial reflection film having a reflectance distribution in directions of an arrow B. The beam splitter 16n may be supported by an arm 16p with a holder 16o. The arm 16p may be supported by a moving table 16q, and the moving table 16q may be supported by a uniaxial stage 16r.

FIGS. 6D and 6E show the beam splitter 16n, the holder 16o, the arm 16p, the moving table 16q, and the uniaxial stage 16r as viewed in a direction perpendicular to the reflection surface of the beam splitter 16n. FIGS. 6B, 6C, and 6E show a state in which the beam splitter 16n and its periphery have been moved to positions different from those in FIGS. 6A and 6D. The uniaxial stage 16r may be configured such that the beam splitter 16n, the holder 16o, the arm 16p and the moving table 16q move in the directions of the arrow B. The uniaxial stage 16r may be controlled by the laser system controller 31 (see FIG. 5). Thus, the beam splitter 16n may be capable of moving in the directions of the arrow B while maintaining the incident angle of the pulse laser beam.

The concave mirrors 16a to 16h may form delay optics. The concave mirrors 16a to 16h may each be a concave mirror having a focal length F (not shown) approximately equal to one another. Of these concave mirrors, the concave mirrors 16c, 16d, 16e, and 16f may be supported by rotating stages 16i, 16j, 16k, and 16m, respectively. The rotating stages 16i, 16j, 16k, and 16m may be capable of rotating the concave mirrors 16c, 16d, 16e, and 16f, respectively, in a plane parallel to the surface of the figure and controlling the postures thereof. The rotating stages 16i, 16j, 16k, and 16m may be controlled by the laser system controller 31 (see FIG. 5). The focal length F may be equivalent to, for example, the distance from the beam splitter 16n to the concave mirror 16a.

### 3.4 Operation of Optical Pulse Stretcher

The pulse laser beam entering the beam splitter 16n from the left side of the figure may be transmitted through the first surface 161 at a high transmittance and then be incident on the partial reflection film of the second surface 162. The pulse laser beam incident on the second surface 162 may be branched into first and second optical paths. Specifically, a part of the pulse laser beam incident on the second surface 162 may be transmitted through the second surface 162 to travel the first optical path as a first output pulse P1. Another part of the pulse laser beam incident on the second surface 162 may be reflected by the second surface 162 to travel the second optical path, and then be reflected by the concave mirror 16a.

When the postures of the concave mirrors 16c, 16d, 16e, and 16f are in a state shown in FIG. 6A, the pulse laser beam reflected by the concave mirror 16a may be reflected by the concave mirrors 16d, 16e, 16h, 16g, 16f, 16c, and 16b in this order, and then be incident on the beam splitter 16n from the upper side of the figure. A part of the pulse laser beam incident on the beam splitter 16n from the upper side of the figure may be reflected by the beam splitter 16n to travel the first optical path as a second output pulse P2. Another part of the pulse laser beam incident on the beam splitter 16n from the upper side of the figure may be transmitted through the beam splitter 16n to travel the second optical path again.

The first output pulse P1, which is a part of the pulse laser beam incident on the beam splitter 16n from the left side of the figure and transmitted therethrough, and the second output pulse P2, which is a part of the pulse laser beam incident on the beam splitter 16n from the upper side of the figure and reflected thereby, may be outputted from the optical pulse stretcher 16 toward the right side of the figure along approximately the same optical path axes with each other. An optical path length of the delay optical path formed by the concave mirrors 16a, 16d, 16e, 16h, 16g, 16f, 16c, and 16b may be equivalent to 16 times as long as the focal length F of each of the concave mirrors 16a to 16h. The delay time of the second output pulse P2 with respect to the first output pulse P1 may be 16F/c, where c represents the speed of light.

The pulse laser beam incident on the beam splitter 16n from the upper side of the figure and transmitted therethrough may be again reflected by the concave mirror 16a, pass through the same delay optical path, and again incident on the beam splitter 16n from the upper side of the figure. A part of the pulse laser beam again incident on the beam splitter 16n from the upper side of the figure may be reflected thereby and outputted from the optical pulse stretcher 16 toward the right side of the figure. By repeating this operation, third and fourth output pulses (not shown) may be outputted along approximately the same optical path axes as those of the first and second output pulses P1 and P2. In this way, the pulse laser beam may be pulse-stretched.

FIG. 6B shows the optical pulse stretcher in which the postures of the concave mirrors 16c, 16d, 16e, and 16f are different from those in FIG. 6A. When the postures of the concave mirrors 16c, 16d, 16e, and 16f are in the state shown in FIG. 6B, the pulse laser beam reflected by the concave mirror 16a may be reflected by the concave mirrors 16d, 16e, 16f, 16c, and 16b in this order. That is, the concave mirrors 16h and 16g may be skipped. In this case, an optical path length of the delay optical path may be equivalent to about 12 times as long as the focal length F of each of the concave mirrors 16a to 16h.

FIG. 6C shows the optical pulse stretcher in which the postures of the concave mirrors 16c, 16d, 16e, and 16f are different from those in FIGS. 6A and 6B. When the postures of the concave mirrors 16c, 16d, 16e, and 16f are in the state shown in FIG. 6C, the pulse laser beam reflected by the concave mirror 16a may be reflected by the concave mirrors 16d, 16c, and 16b in this order. That is, the concave mirrors 16e, 16h, 16g, and 16f may be skipped. In this case, an optical path length of the delay optical path may be equivalent to about 8 times as long as the focal length F of each of the concave mirrors 16a to 16h.

As seen above, the optical path length of the delay optical path may be changed to 8F, 12F, and 16F in accordance with the postures of the concave mirrors 16c, 16d, 16e, and 16f. In any of these cases, a transfer image of a cross-section of the pulse laser beam incident on the second surface 162 of the beam splitter 16n from the left side of the figure may be formed on the second surface 162 of the beam splitter 16n. A change in the optical path length of the delay optical path may cause a change in the delay time of the second output pulse P2 or the third or fourth output pulse with respect to the first output pulse P1. Thus, the time-domain pulse waveform of the pulse laser beam outputted from the optical pulse stretcher 16 may be changed. The rotating stages 16i, 16j, 16k, and 16m may correspond to optical path length changing units of the present disclosure.

Moving the position of the beam splitter 16n in the directions of the arrow B using the uniaxial stage 16r may cause a change in the reflectance of the beam splitter 16n reflecting the pulse laser beam. The change in the reflectance of the beam splitter 16n reflecting the pulse laser beam may cause a change in optical intensity ratio of the second output pulse P2 or the third or fourth output pulse to the first output pulse P1. Thus, the time-domain pulse waveform of the pulse laser beam outputted from the optical pulse stretcher 16 may be changed. The uniaxial stage 16r may correspond to a reflectance changing unit of the present disclosure.

As seen above, the changes in the reflectance of the beam splitter and in the optical path length of the delay optical path in the optical pulse stretcher 16 may achieve change in time interval between each adjacent two pulses of the first to fourth output pulses or change in the optical intensity ratio between each adjacent two pulses of the first to fourth output pulses. The optical pulse stretcher 16 may correspond to a time-domain pulse waveform changing apparatus of the present disclosure.

While the eight concave mirrors are shown in FIGS. 6A to 6E as an example, the present disclosure is not limited to this example. More concave mirrors may be disposed in a similar manner.

The other aspects may be similar to those of the laser annealing apparatus described with reference to FIGS. 1 to 3.

### 3.5 Process by Annealing Controller

### 3.5.1 Main Flow

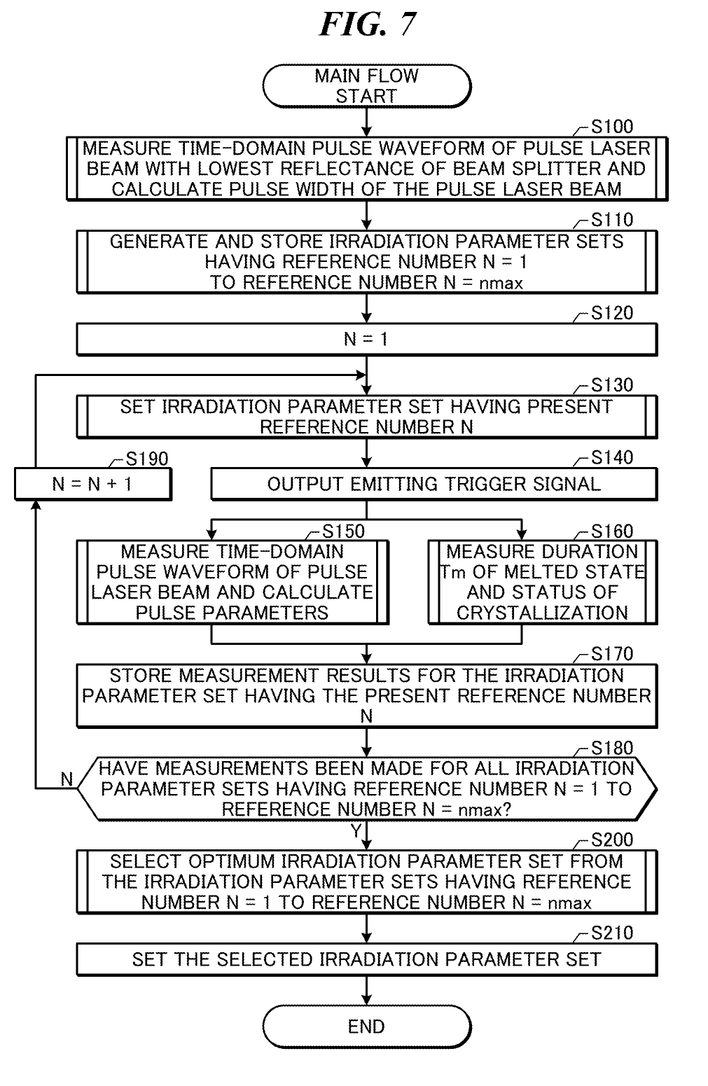

FIG. 7 is a flowchart showing a process to set a time-domain pulse waveform performed by the annealing controller shown in FIG. 5. In the following process, the annealing controller 45 may perform annealing on multiple irradiation conditions, measure durations of melted states on the respective irradiation conditions, and select an optimum irradiation condition.

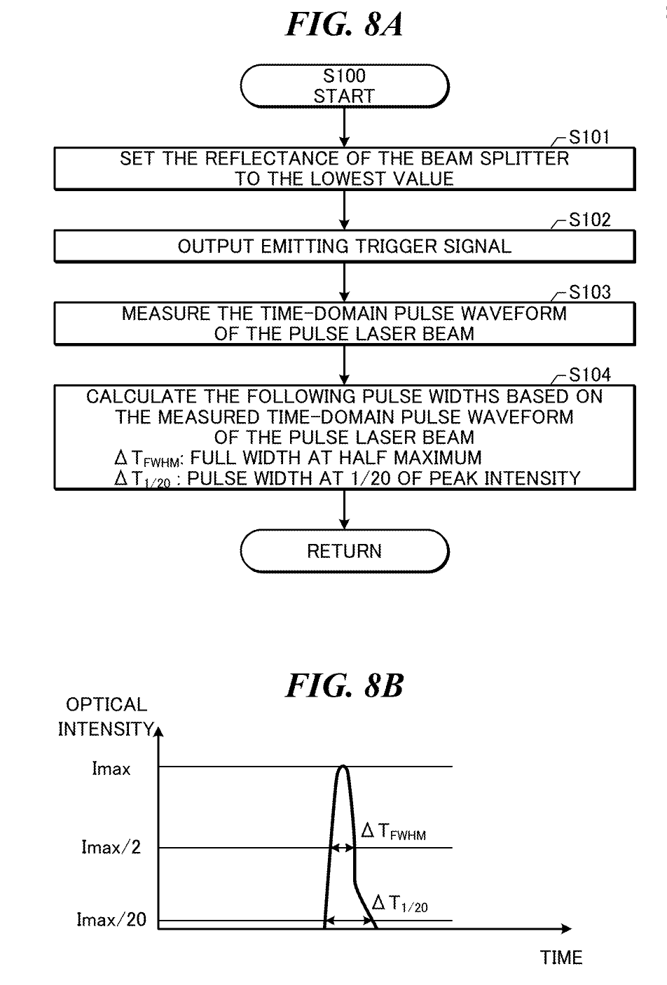

First, in S100, the annealing controller 45 may measure the time-domain pulse waveform of the pulse laser beam with the lowest reflectance of the beam splitter 16n, and calculate a pulse width of the pulse laser beam. Thus, it is possible to acquire a waveform close to the time-domain pulse waveform of the pulse laser beam that has been outputted from the laser apparatus 2 but has yet to enter the optical pulse stretcher 16. Details of this process will be described later with reference to FIGS. 8A and 8B.

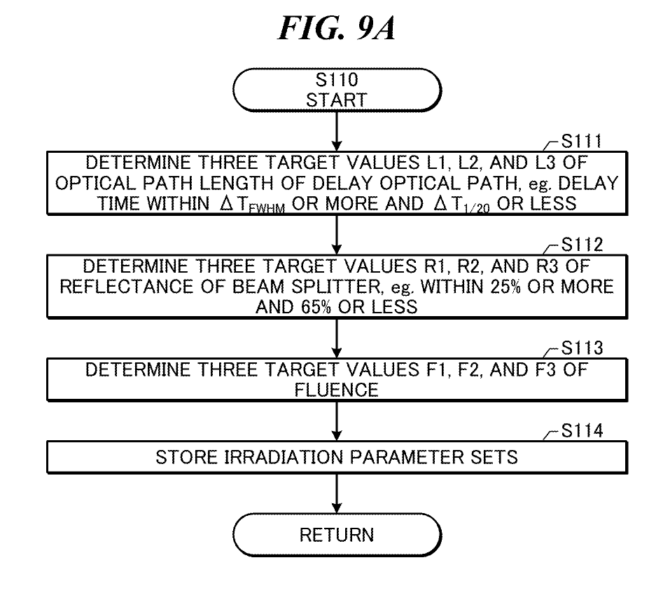

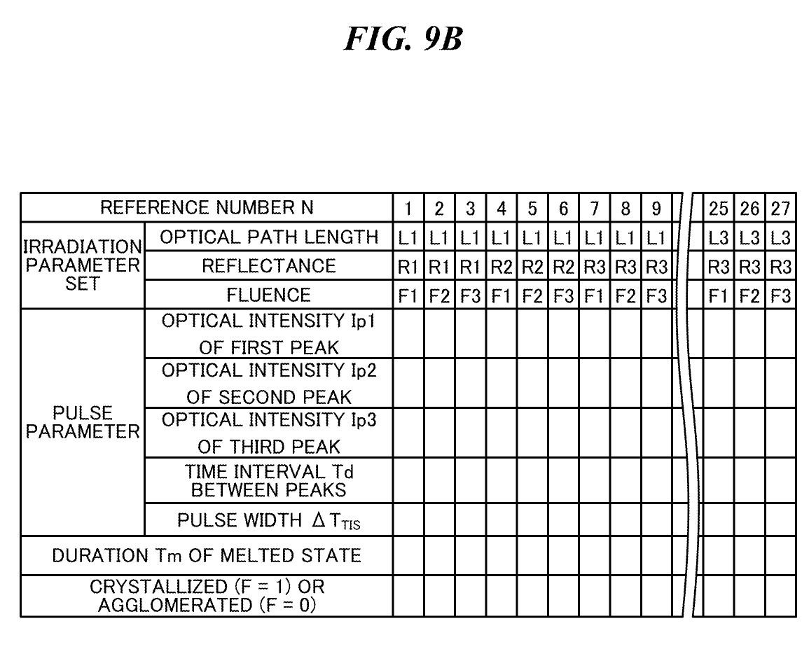

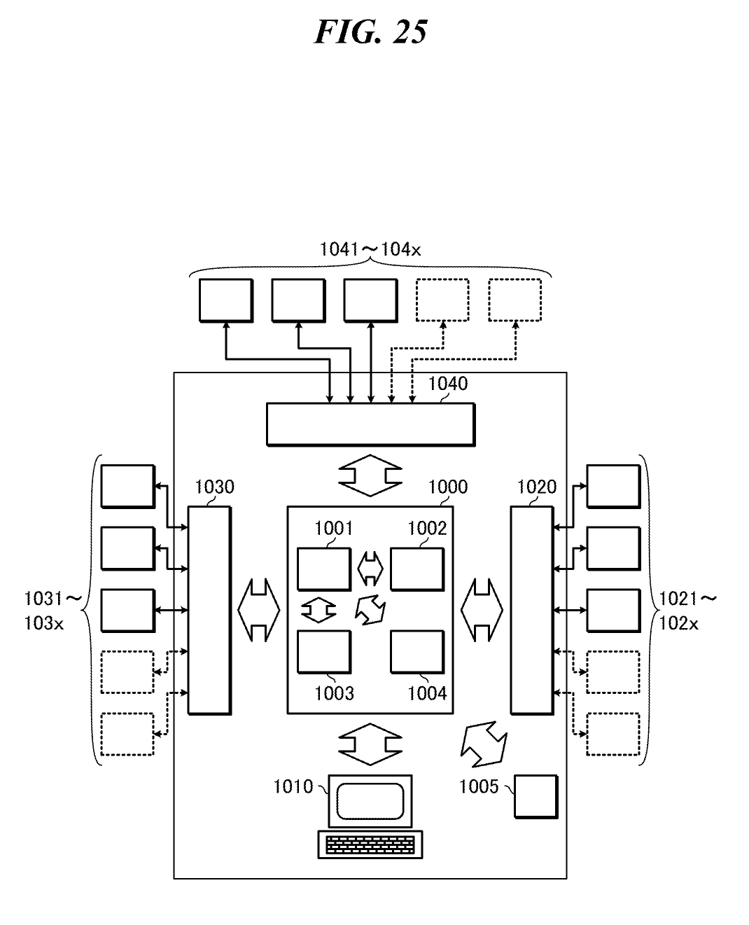

Then, in S110, the annealing controller 45 may generate irradiation parameter sets having reference number N=1 to reference number N=nmax and store the irradiation parameter sets in a memory. The memory will be described later with reference to FIG. 25. The irradiation parameter sets may include nmax number of combinations of a target value of the optical path length of the delay optical path of the optical pulse stretcher 16, a target value of the reflectance of the beam splitter 16n, and a target value of the fluence of the pulse laser beam on the workpiece 43e. Details of S110 will be described later with reference to FIG. 9A. The irradiation parameter sets may be stored in a data table format to be described with reference to FIG. 9B.

Each of the irradiation parameter sets may include parameters for generating the time-domain pulse waveform and the target value of the fluence on the workpiece 43e. The parameters for generating the time-domain pulse waveform may be parameters required to generate a time-domain pulse waveform and may include the target value of the reflectance of the beam splitter 16n and the target value of the optical path length of the delay optical path of the optical pulse stretcher 16.

Then, in S120, the annealing controller 45 may set the value of the reference number N to 1.

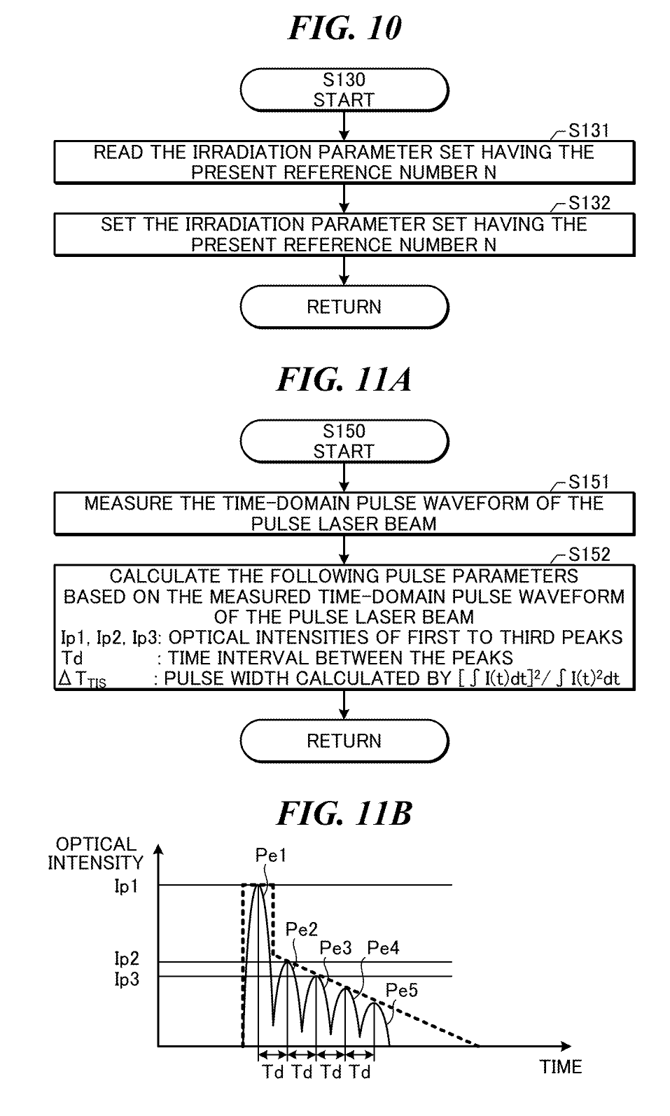

Then, in S130, the annealing controller 45 may set an irradiation parameter set having the present reference number N for the laser system 3a. Specifically, the annealing controller 45 may send the target value of the optical path length of the delay optical path of the optical pulse stretcher 16, the target value of the reflectance of the beam splitter 16n, and the target value of the fluence on the workpiece 43e to the laser system controller 31. Details of this process will be described later with reference to FIG. 10.

Then, in S140, the annealing controller 45 may output the emitting trigger signal to the laser system controller 31.

Then, the annealing controller 45 may proceed to S150 and S160. S150 and S160 may be performed in parallel.

In S150, the annealing controller 45 may measure the time-domain pulse waveform of the pulse laser beam outputted from the optical pulse stretcher 16 using the time-domain pulse waveform measuring unit 19 and calculate one or more pulse parameters. The pulse parameters may include values calculated based on the time-domain pulse waveform of the pulse laser beam measured using the time-domain pulse waveform measuring unit 19 and may include the following values:

Ip1, Ip2, Ip3: optical intensities of first to third peaks

Td: a time interval between the peaks

ΔT_{TIS}: a pulse width calculated using [∫I(t)dt]²/∫I(t)²dt

Details of this process to calculate the pulse parameters will be described later with reference to FIGS. 11A and 11B.

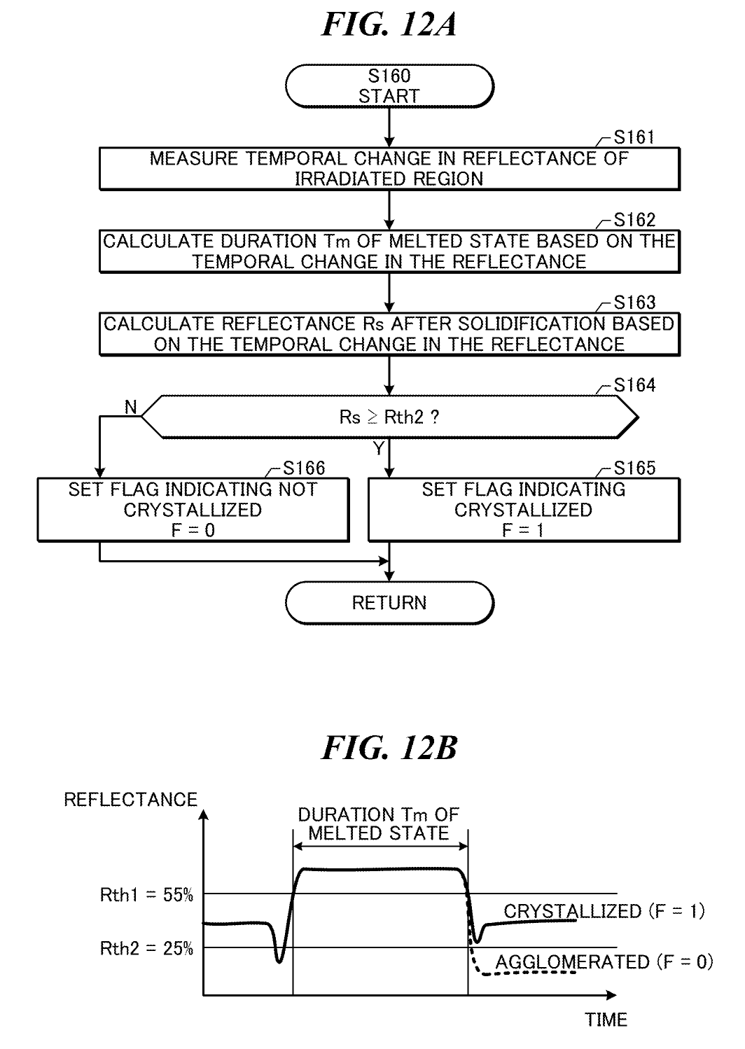

In S160, the annealing controller 45 may measure a duration Tm of a melted state and a status of crystallization of the workpiece 43e based on the temporal change in the reflectance of the irradiated region of the workpiece 43e measured using the optical sensor 44c. The measurement of the status of crystallization may include a determination on whether or not the irradiated region is crystallized. Details of this process will be described later with reference to FIGS. 12A and 12B.

After S150 and S160, the annealing controller 45 may proceed to S170.

In S170, the annealing controller 45 may store, in the memory, the measurement results of S150 and S160 with respect to the irradiation parameter set for the present reference number N. The measurement results may be stored in a data table format to be described with reference to FIG. 9B.

Then, in S180, the annealing controller 45 may determine whether measurements have been made with respect to all irradiation parameter sets for reference number N=1 to reference number N=nmax. If measurements have not been made with respect to all the irradiation parameter sets, the annealing controller 45 may proceed to S190, If measurements have been made with respect to all the irradiation parameter sets, the annealing controller 45 may proceed to S200.

In S190, the annealing controller 45 may update the value of the reference number N by incrementing the value of the reference number N by 1. After S190, the annealing controller 45 may return to S130.

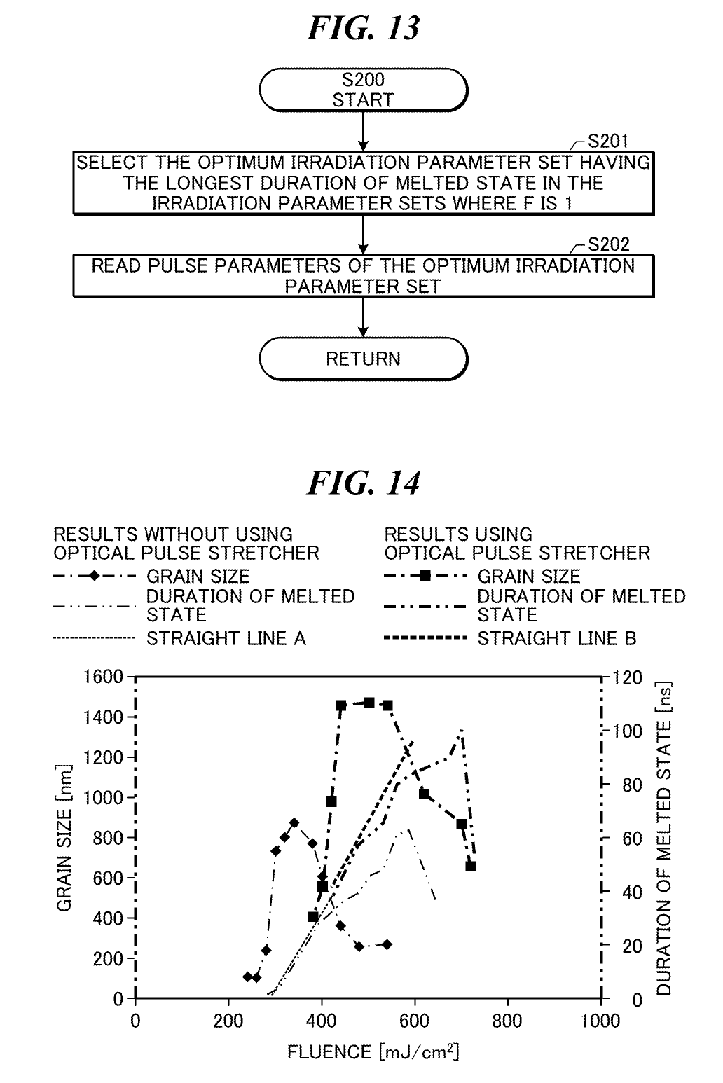

In S200, the annealing controller 45 may select an optimum irradiation parameter set from the irradiation parameter sets having reference number N=1 to reference number N=nmax. Details of this process will be described later with reference to FIG. 13.

Then, in S210, the annealing controller 45 may set the selected irradiation parameter set for the laser system 3a. Specifically, the annealing controller 45 may send the target value of the optical path length of the delay optical path of the optical pulse stretcher 16, the target value of the reflectance of the beam splitter 16n, and the target value of the fluence on the workpiece 43e to the laser system controller 31. This process may be similar to S130 except that the reference number N of the irradiation parameter set may be different.

After S210, the annealing controller 45 may end the process of this flowchart. However, after performing execution of this flowchart, the annealing controller 45 may further set multiple irradiation conditions with small intervals in the vicinity of the selected irradiation condition in a second execution of this flowchart.

### 3.5.2 Details of S100

FIG. 8A is a flowchart showing details of the process shown in FIG. 7 to calculate a pulse width with the lowest reflectance of the beam splitter. The annealing controller 45 may perform the process shown in FIG. 8A as a subroutine of S100 shown in FIG. 7.

First, in S101, the annealing controller 45 may set the reflectance of the beam splitter 16n to the lowest value. The reflectance of the beam splitter 16n may be set by controlling the uniaxial stage 16r to move the beam splitter 16n.

Then, in S102, the annealing controller 45 may output the emitting trigger signal to the laser system controller 31.

In S103, the annealing controller 45 may measure the time-domain pulse waveform of the pulse laser beam outputted from the optical pulse stretcher 16 using the time-domain pulse waveform measuring unit 19.

Then, in S104, the annealing controller 45 may calculate the following pulse widths based on the measured time-domain pulse waveform of the pulse laser beam:

ΔT_{FWHM}: full width at half maximum

ΔT_{1/20}: 5% full width

FIG. 8B shows an example of the time-domain pulse waveform of the pulse laser beam outputted from the optical pulse stretcher with the lowest reflectance of the beam splitter. The above-described ΔT_{FWHM} may be a pulse width of a portion having an optical intensity of Imax/2 where Imax represents the peak intensity of the pulse laser beam. The above-described ΔT_{1/20} may be a pulse width of a portion having an optical intensity of Imax/20.

After S104, the annealing controller 45 may end the process of this flowchart.

### 3.5.3 Details of S110

FIG. 9A is a flowchart showing details of the process shown in FIG. 7 to generate the irradiation parameter sets. The annealing controller 45 may perform the process shown in FIG. 9A as a subroutine of S110 shown in FIG. 7.

First, in S111, the annealing controller 45 may determine three optical path lengths L1, L2, and L3 of the delay optical path of the optical pulse stretcher 16. The optical path lengths of the delay optical path may be selected such that the delay time of the pulse laser beam passed through the delay optical path falls within ΔT_{FWHM} or more and ΔT_{1/20} or less.

Then, in S112, the annealing controller 45 may determine three reflectances R1, R2, and R3 of the beam splitter 16n. The reflectances of the beam splitter 16n may be selected, for example, in a range of 25% or more and 65% or less. If the reflectance of the beam splitter 16n is less than 25%, sufficient effects of pulse stretch may not be obtained, and second and subsequent peaks to be discussed later with reference to FIG. 11B may not appear. If the reflectance of the beam splitter 16n is more than 65%, a ratio of an optical intensity of a second peak to an optical intensity of a first peak to be discussed later with reference to FIG. 11B may exceed 75% and thus an ideal time-domain pulse waveform may not be obtained.

Then, in S113, the annealing controller 45 may determine three target values F1, F2, and F3 of the fluence of the pulse laser beam on the workpiece 43e. The target values of the fluence of the pulse laser beam on the workpiece 43e may be determined such that at least a part of the workpiece 43e is melted.

Then, in S114, the annealing controller 45 may store, in the memory, the irradiation parameter sets determined in S111 to S113.

FIG. 9B shows an example of a data structure where the irradiation parameter sets are stored in a table format. If three values are determined with respect to each of the target value of the optical path length of the delay optical path of the optical pulse stretcher 16, the target value of the reflectance of the beam splitter 16n, and the target value of the fluence of the pulse laser beam on the workpiece 43e as described above, 27 irradiation parameter sets may be obtained. A table shown in FIG. 9B may contain irradiation parameter sets having reference number N=1 to reference number N=27.

In S170, measurement results with respect to each of the 27 irradiation parameter sets may be stored in the table shown in FIG. 9B.

Note that the number of irradiation parameter sets need not be 27. The number of irradiation parameter sets may be 2 or more.

After S114, the annealing controller 45 may end the process of this flowchart.

### 3.5.4 Details of S130

FIG. 10 is a flowchart showing details of the process shown in FIG. 7 to set an irradiation parameter set for the laser system. The annealing controller 45 may perform the process shown in FIG. 10 as a subroutine of S130 shown in FIG. 7.

First, in S131, the annealing controller 45 may read the irradiation parameter set having the present reference number N.

Then, in S132, the annealing controller 45 may set the read irradiation parameter set for the laser system 3a. The laser system controller 31 of the laser system 3a may receive the irradiation parameter set from the annealing controller 45. The laser system controller 31 may control the rotating stages 16i, 16j, 16k, and 16m for rotating the concave mirrors 16c, 16d, 16e, and 16f in the optical pulse stretcher 16 so that the optical path length of the delay optical path of the optical pulse stretcher 16 comes close to the target value. The laser system controller 31 may also control the uniaxial stage 16r for moving the beam splitter 16n so that the reflectance of the beam splitter 16n comes close to the target value. The laser system controller 31 may also control the transmittance of the attenuator 18 so that the fluence of the pulse laser beam on the workpiece 43e comes close to the target value. The attenuator 18 may correspond to a fluence changing unit of the present disclosure.

After S132, the annealing controller 45 may end the process of this flowchart.

### 3.5.5 Details of S150

FIG. 11A is a flowchart showing details of the process shown in FIG. 7 to calculate the pulse parameters. The annealing controller 45 may perform the process shown in FIG. 11A as a subroutine of S150 shown in FIG. 7.

First, in S151, the annealing controller 45 may measure the time-domain pulse waveform of the pulse laser beam outputted from the optical pulse stretcher 16 using the time-domain pulse waveform measuring unit 19.

FIG. 11B shows an example of the time-domain pulse waveform of the pulse laser beam outputted from the optical pulse stretcher. A peak having the highest optical intensity in the waveform shown in FIG. 11B may be a first peak Pe1 formed by the first output pulse P1 (see FIG. 6A). The first output pulse P1 is a part of thee pulse laser beam incident on the beam splitter 16n from the left side of FIG. 6A and transmitted therethrough.

The waveform shown in FIG. 11B may include the first peak Pe1, and include a second peak Pe2 formed by the second output pulse P2. The second output pulse P2 is a part of the pulse laser beam incident on the beam splitter 16n from the upper side of FIG. 6A and then reflected thereby. The optical intensity Ip2 of the second peak Pe2 may be lower than the optical intensity Ip1 of the first peak Pe1.

A third peak Pe3 may be formed by the third output pulse. The third output pulse is a part of the pulse laser beam incident on the beam splitter 16n from the upper side of FIG. 6A, transmitted therethrough, again incident on the beam splitter 16n from the upper side of FIG. 6A, and reflected thereby. The optical intensity Ip3 of the third peak Pe3 may be lower than the optical intensity Ip2 of the second peak Pe2. Likewise, a fourth peak Pe4 and a fifth peak Pe5 having still lower optical intensities may be present subsequent to the third peak Pe3.

The time difference between the first peak Pe1 and the second peak Pe2 may be measured as the time interval Td between peaks. The time difference between the second peak Pe2 and the third peak Pe3 may be approximately equal to the time interval Td between peaks. That is, the time interval Td between peaks may be L/c, where L represents the optical path length of the delay optical path, and c represents the speed of light.

The optical intensity Ip1 of the first peak Pe1 may be set high so as to give energy for melting the workpiece to the workpiece. To suppress laser ablation, it is preferable that the optical intensity Ip1 of the first peak Pe1 is not too high. The optical intensities of the second peak Pe2 and subsequent peaks may be lower than the optical intensity Ip1 of the first peak Pe1, since the second peak Pe2 and subsequent peaks only have to maintain the melted state of the workpiece.

Referring back to FIG. 11A, in S152, the annealing controller 45 may calculate the following pulse parameters based on the measured time-domain pulse waveform of the pulse laser beam.

Ip1, Ip2, Ip3: optical intensities of the first to third peaks

Td: a time interval between the peaks

ΔT_{TIS}: a pulse width calculated using [∫I(t)dt]²/∫I(t)²dt

After S152, the annealing controller 45 may end the process of this flowchart.

### 3.5.6 Details of S160

FIG. 12A is a flowchart showing details of the process shown in FIG. 7 to measure the duration of the melted state and the status of crystallization. The annealing controller 45 may perform the process shown in FIG. 12A as a subroutine of S160 shown in FIG. 7.

First, in S161, the annealing controller 45 may measure the temporal change in the reflectance of the irradiated region of the workpiece 43e reflecting the laser beam. Specifically, the annealing controller 45 may measure the optical intensity of the reflected light of the laser beam reflected by the irradiated region of the workpiece 43e using the optical sensor 44c. The annealing controller 45 may measure the temporal change in the reflectance based on the optical intensity of the reflected light.

FIG. 12B shows an example of the temporal change in the reflectance of the irradiated region of the workpiece reflecting the pulse laser beam. As shown in FIG. 12B, the reflectance may be about 40% before irradiating the workpiece 43e with the pulse laser beam.

Then, when the irradiation of the workpiece 43e with the pulse laser beam is started, the irradiated region of the workpiece 43e may start to melt. While the irradiated region of the workpiece 43e includes both a solid portion and a liquid portion, the surface shape of the irradiated region of the workpiece 43e may be complicated and thus the reflectance may be temporarily in a low level.

When the irradiated region of the workpiece 43e is covered by the liquid surface, the surface shape of the irradiated region of the workpiece 43e may be flattened. Thus, the reflectance may become higher than that before irradiating the workpiece 43e with the pulse laser beam, that is, the reflectance may rise to about 70%.

Then, when the irradiation of the workpiece 43e with the pulse laser beam is ended, the irradiated region of the workpiece 43e may start to solidify and the reflectance may fall. While the irradiated region of the workpiece 43e includes both a solid portion and a liquid portion, the surface shape of the irradiated region of the workpiece 43e may be complicated and thus the reflectance may be in a low level.

When the irradiated region of the workpiece 43e solidifies completely and crystallizes, the reflectance may rise to a value equivalent to that before irradiating the workpiece 43e with the pulse laser beam. In contrast, if the irradiated region of the workpiece 43e fails to crystallize, agglomerate may be formed in the irradiated region of the workpiece 43e. The surface shape of the irradiated region may thus be complicated, causing dispersion of the pulse laser beam. Thus, the reflectance may become lower than that before irradiating the workpiece 43e with the pulse laser beam, that is, the reflectance may fall to 10%.

Referring back to FIG. 12A, in S162, the annealing controller 45 may calculate a duration Tm of the melted state based on the temporal change in the reflectance. The duration Tm of the melted state may be calculated as the time period during which a state where the reflectance is higher than a first threshold Rth1 has continued. The first threshold Rth1 may be, for example, about 55%.

Then, in S163, the annealing controller 45 may calculate a reflectance Rs after the solidification based on the temporal change in the reflectance. The reflectance after the solidification may be calculated as a reflectance when a predetermined time has passed after expiration of the duration Tm of the melted state.

Then, in S164, the annealing controller 45 may determine whether the reflectance Rs after the solidification is equal to or higher than a second threshold Rth2. The second threshold Rth2 may be lower than the first threshold Rth1. The second threshold Rth2 may be, for example, about 25%.

If the reflectance Rs after the solidification is equal to or higher than the second threshold Rth2 (S164: YES), the annealing controller 45, in S155, may determine that the irradiated region of the workpiece 43e has crystallized and then set a flag indicating the determination result. Specifically, a variable F may be set to 1.

If the reflectance Rs after the solidification is not equal to or higher than the second threshold Rth2 (S164: NO), the annealing controller 45, in S166, may determine that the irradiated region of the workpiece 43e has not crystallized and then set a flag indicating the determination result. Specifically, the variable F may be set to 0.

After S165 or S166, the annealing controller 45 may end the process of this flowchart.

### 3.5.7 Details of S200

FIG. 13 is a flowchart showing details of the process shown in FIG. 7 to select the optimum irradiation parameter set. The annealing controller 45 may perform the process shown in FIG. 13 as a subroutine of S200 shown in FIG. 7.

First, in S201, the annealing controller 45 may select an irradiation parameter set having the longest duration of the melted state in the irradiation parameter sets where the variable F is set to 1. The selected irradiation parameter set may be an optimum irradiation parameter set. The reason why an irradiation parameter set is selected from the irradiation parameter sets where the variable F is set to 1 is to select an irradiation parameter set on which the workpiece is crystallized. The reason why an irradiation parameter set having the longest duration of the melted state is selected will be described later with reference to FIG. 14.

Then, in S202, the annealing controller 45 may read the pulse parameters of the optimum irradiation parameter set from the data stored in S170.

After S202, the annealing controller 45 may end the process of this flowchart.

### 3.6 Selecting Irradiation Condition.

FIG. 14 is a graph showing a relationship between the fluence of the pulse laser beam with which the workpiece is irradiated and the size of each crystal grain formed in the workpiece, and a relationship between the fluence of the pulse laser beam with which the workpiece is irradiated and the duration of the melted state. FIG. 14 shows measurement. results without using an optical pulse stretcher, and shows measurement results using an optical pulse stretcher as described with reference to FIGS. 5 and 6A to 6E.

In either case where an optical pulse stretcher is used or not, the duration of the melted state may become longer as the fluence of the pulse laser beam becomes higher. However, if the fluence of the pulse laser beam becomes higher and thus the duration of the melted state becomes longer, the workpiece may tend to be damaged, failing to obtain a preferable large grain size.

Nevertheless, it has been found that, when an optical pulse stretcher is used, a preferable large grain size may be obtained compared to when an optical pulse stretcher is not used, even if the fluence of the pulse laser beam becomes higher to some extent and thus the duration of the melted state becomes longer to some extent.

Thus, the present disclosure uses an optical pulse stretcher so that the workpiece may be irradiated with the pulse laser beam where the second and third peaks have lower optical intensities than the first peak. By selecting an irradiation condition where the workpiece is crystallized and the duration of the melted state is maximized, polycrystalline silicon having a large grain size may be obtained.

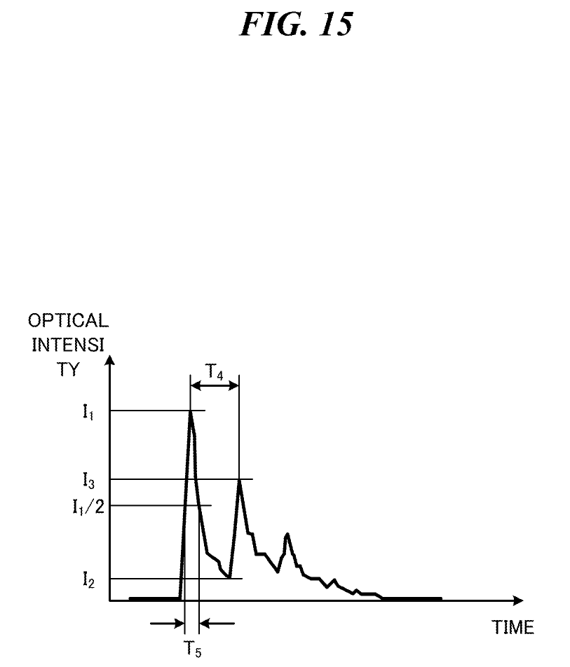

FIG. 15 is a graph showing an example of a preferable time-domain pulse waveform. The time-domain pulse waveform shown in FIG. 15 may include first to third peaks.

The optical intensity I₁ of the first peak is preferably 36 MW/cm² or more and 90 MW/cm² or less.

The lowest intensity I₂ between the first and second peaks is preferably 13 MW/cm² or more and equal to or lower than the optical intensity I₃ of the second peak.

The ratio of the optical intensity I₃ of the second peak to the optical intensity I₁ of the first peak is preferably 74% or less.

The time interval T₄ between the first and second peaks is preferably 12 ns or more and 100 ns or less, or equal to or greater than the full width at half maximum of the first peak and equal to or smaller than the 5% full width of the first peak.

The full width T₅ at half maximum of the first peak is preferably 15 ns or more and 50 ns or less.

### 4. Variation of Beam Splitter (Second Embodiment)

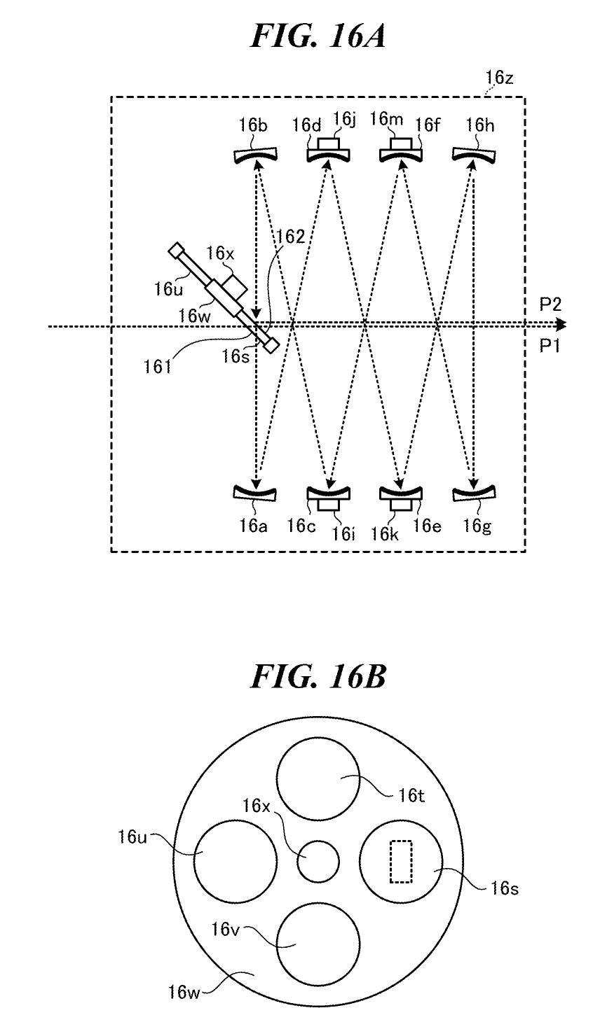

FIG. 16A shows a configuration of an optical pulse stretcher used in a laser annealing apparatus of a second embodiment of the present disclosure. FIG. 16B shows a plurality of beam splitters used in the optical pulse stretcher shown in FIG. 16A as viewed in a direction perpendicular to the reflection surfaces of the beam splitters.

An optical pulse stretcher 16z used in the second embodiment may include beam splitters 16s, 16t, 16u, and 16v. The beam splitters 16s, 16t, 15u, and 16v may have different reflectances from each other. The beam splitters 16s, 16t, 16u, and 16v may be supported by a holder 16w. The holder 16w may be rotatably supported by a stepping motor 16x.

A laser system controller 31 (see FIG. 5) may be capable of selectively locating the beam splitters 16s, 16t, 16u, and 16v in the optical path of the pulse laser beam by controlling the stepping motor 16x. Whichever of the beam splitters 16s, 16t, 16u, and 16v is located in the optical path of the pulse laser beam, incident angles of the pulse laser beam may be the same, and the reflectances of the beam splitters may be different. Thus, the time-domain pulse waveform of the pulse laser beam outputted from the optical pulse stretcher 16z may be changed. The stepping motor 16x may correspond to a reflectance changing unit of the present disclosure.

The other elements may be similar to those of the first embodiment.

### 5. Variation in Selecting Irradiation Condition (Third Embodiment)

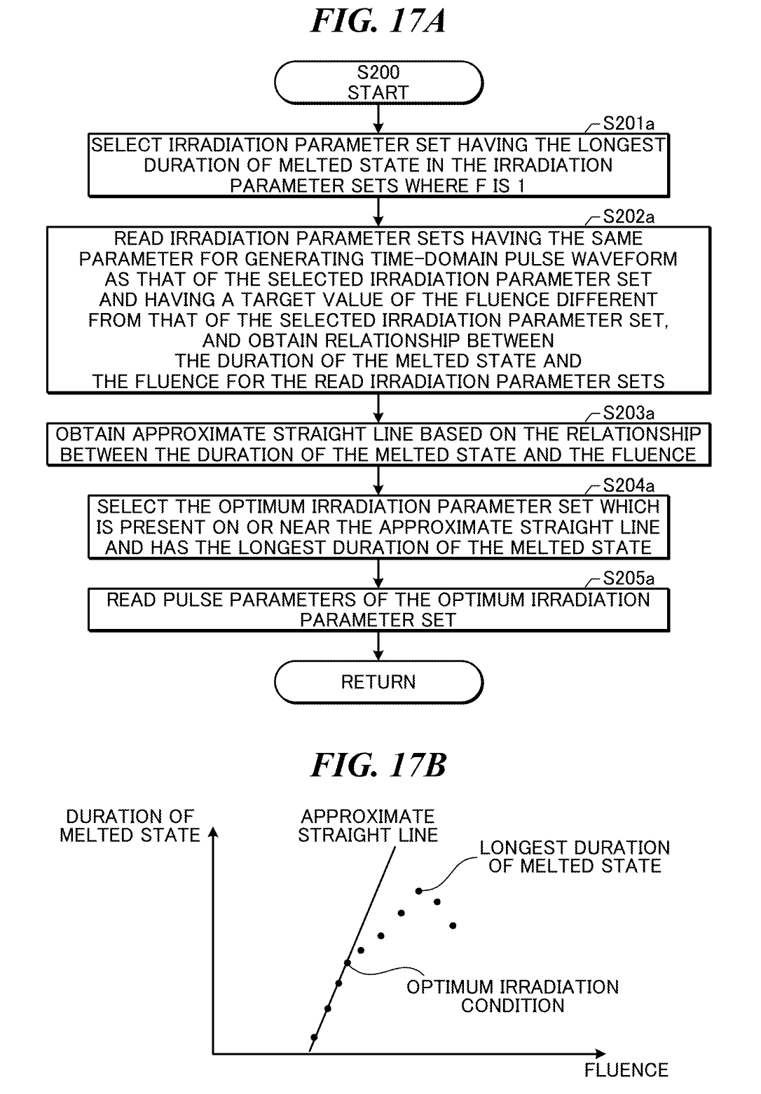

FIG. 17A is a flowchart showing details of a process to select an optimum irradiation parameter set performed by a laser annealing apparatus of a third embodiment of the present disclosure. The configuration of the laser annealing apparatus of the third embodiment may be similar to that of the laser annealing apparatus of the first or second embodiment. The annealing controller 45 may perform the process shown in FIG. 17A as a subroutine of S200 shown in FIG. 7.

Referring back to FIG. 14, if an optical pulse stretcher is used, a curve indicating the relationship between the fluence of the pulse laser beam with which the workpiece is irradiated and the duration of the melted state may include a portion where the duration of the melted state is increased with increases in the fluence approximately in parallel with an approximate straight line B. If the fluence is further increased, the curve indicating the relationship between the fluence and the duration of the melted state may leave the straight line B and then the duration of the melted state may be reduced. The grain size may be approximately maximized where the curve indicating the relationship between the fluence and the duration of the melted state leaves the straight line B.

The same thing may be derived from the relationship between a curve and an approximate straight line A in the case without using an optical pulse stretcher. Thus, in the third embodiment, an optimum irradiation parameter set may be selected by performing the following process.

In S201a of FIG. 17A, the annealing controller 45 may select an irradiation parameter set having the longest duration of the melted state in the irradiation parameter sets where the variable F is set to 1.

Then, in S202a, the annealing controller 45 may read, from the data stored in S110 (see FIG. 7), multiple irradiation parameter sets each having the same parameter for generating the time-domain pulse waveform as that of the selected irradiation parameter set and having a target value of the fluence different from that of the selected irradiation parameter set. The annealing controller 45 may read, from the data stored in S170, the duration of the melted state for each of the read irradiation parameter sets. The annealing controller 45 may thus obtain the relationship between the duration of the melted state and the fluence. That is, the annealing controller 45 may obtain the relationship between the duration of the melted state and the fluence under the condition where the parameter for generating the time-domain pulse waveform of the selected irradiation parameter set is fixed and the fluence is varied.

Then, in S203a, the annealing controller 45 may obtain an approximate straight line based on the relationship between the duration of the melted state and the fluence.

FIG. 17B shows an example of the relationship between the duration of the melted state and the fluence. In S203a, the annealing controller 45 may obtain an approximate straight line as shown in FIG. 17B. Such an approximate straight line may be obtained with respect to a region having a small fluence rather than a portion having the longest duration of the melted state.

Then, in S204a, the annealing controller 45 may select, as an optimum irradiation parameter set, an irradiation parameter set which is present on or near the approximate straight line and has the longest duration of the melted state.

Then, in S205a, the annealing controller 45 may read the pulse parameters of the optimum irradiation parameter set from the data stored in S170.

After S205a, the annealing controller 45 may end the process of this flowchart.

The other processes may be similar to those described with reference to FIGS. 7 to 13. Note that in the third embodiment, the number of fluence samples is preferably more than 3 in S113 described with reference to FIG. 9A. For example, the number of fluence samples is preferably in a range of 4 to 10.

According to the third embodiment, a condition for obtaining a large grain size may be extracted based on the relationship between the fluence and the duration of the melted state. Thus, a better polycrystalline silicon film than that of the first or second embodiment may be formed.

### 6. Laser Annealing Apparatus Including Plurality of Laser Units (Fourth Embodiment)

### 6.1 Configuration and Operation

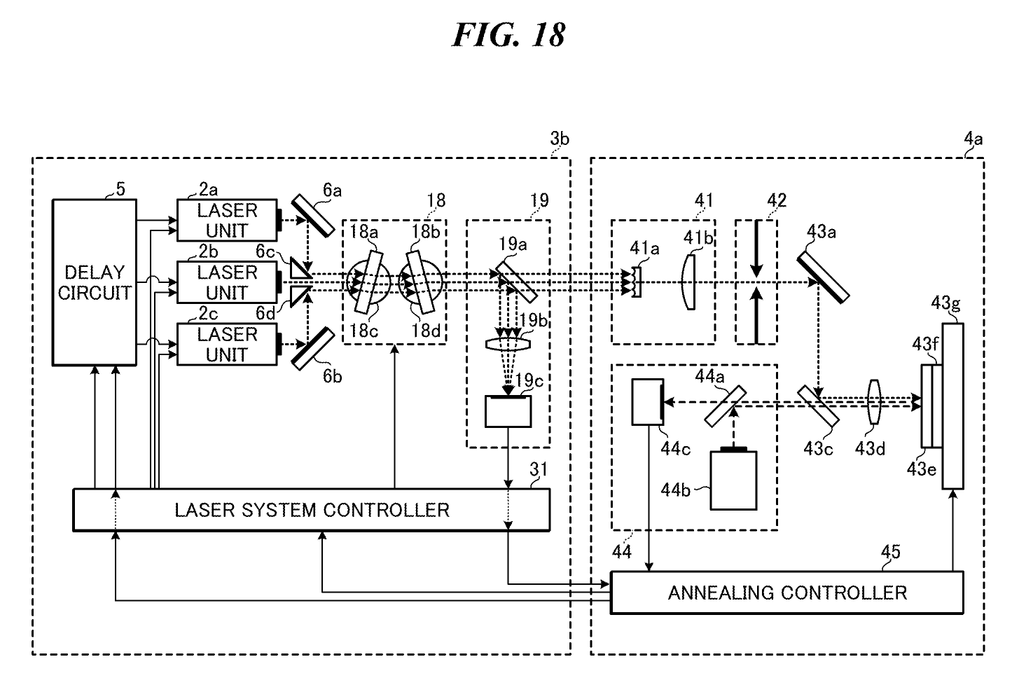

FIG. 18 schematically shows a configuration of a laser annealing apparatus of a fourth embodiment of the present disclosure. In the laser annealing apparatus of the fourth embodiment, a laser system 3b may include first, second, and third laser units 2a, 2b, and 2c, a delay circuit 5, high-reflective mirrors 6a and 6b, and knife-edge mirrors 6c and 6d. In the laser annealing apparatus of the fourth embodiment, an optical pulse stretcher is not necessary in the laser system 3b.

The other elements may be similar to those of the first to third embodiments.

The first, second, and third laser units 2a, 2b, and 2c may each have a configuration similar to that of the laser apparatus 2. Each laser unit may receive data on target pulse energy from the laser system controller 31. The data on the target pulse energy may vary for each of the first, second, and third laser units 2a, 2b, and 2c. Based on the received data on the target pulse energy, the laser controller 30 in each laser unit may set the charging voltage with which the charger 12 charges the charging capacitor C0.

The delay circuit 5 may receive delay time setting data from the laser system controller 31. The delay circuit 5 may also receive an emitting trigger signal outputted from the annealing controller 45 through the laser system controller 31. Upon an expiration of the set delay time after receiving the emitting trigger signal, the delay circuit 5 may output oscillation trigger signals to the first, second, and third laser units 2a, 2b, and 2c in this order.

The high-reflective mirror 6a and the knife-edge mirror 6c may reflect a pulse laser beam outputted from the first laser unit 2a with a high reflectance. The pulse laser beam outputted from the first laser unit 2a may thus be directed to an optical path that is approximately parallel with and close to an optical path of a pulse laser beam outputted from the second laser unit 2b, and be outputted toward the attenuator 18.

The high-reflective mirror 6b and the knife-edge mirror 6d may reflect a pulse laser beam outputted from the third laser unit 2c with a high reflectance. The pulse laser beam outputted from the third laser unit 2c may thus be directed to an optical path that is approximately parallel with and close to the optical path of the pulse laser beam outputted from the second laser unit 2b, and be outputted toward the attenuator 18.

The pulse laser beams outputted from the first, second, and third laser units 2a, 2b, and 2c may travel through the attenuator 18 and the time-domain pulse waveform measuring unit 19 and then enter the beam homogenizer 41. The beam homogenizer 41 may perform Koehler-illumination on the slit 42, and the optical paths of these pulse laser beams may coincide with each other at the slit 42. Thus, it is possible to make uniform the optical intensity profiles of the beams at the opening of the slit 42.

### 6.2 Process by Annealing Controller

### 6.2.1 Main Flow

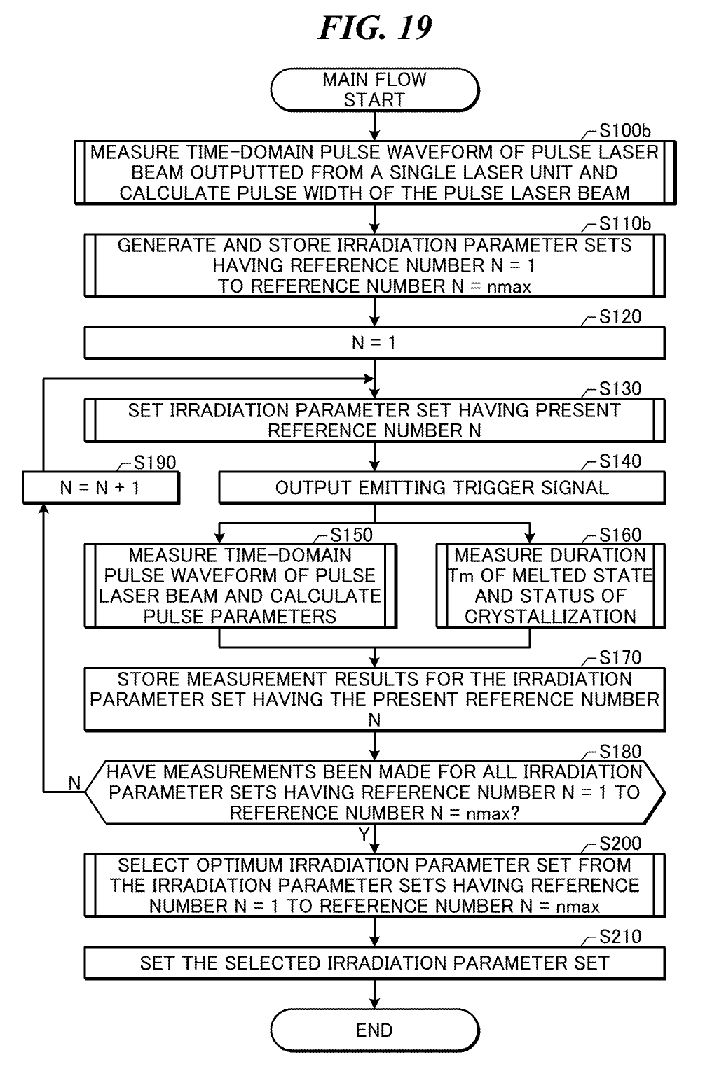

FIG. 19 is a flowchart showing a process to set a time-domain pulse waveform performed by the annealing controller shown in FIG. 18. The annealing controller 45 may select an optimum irradiation condition by performing the following process.

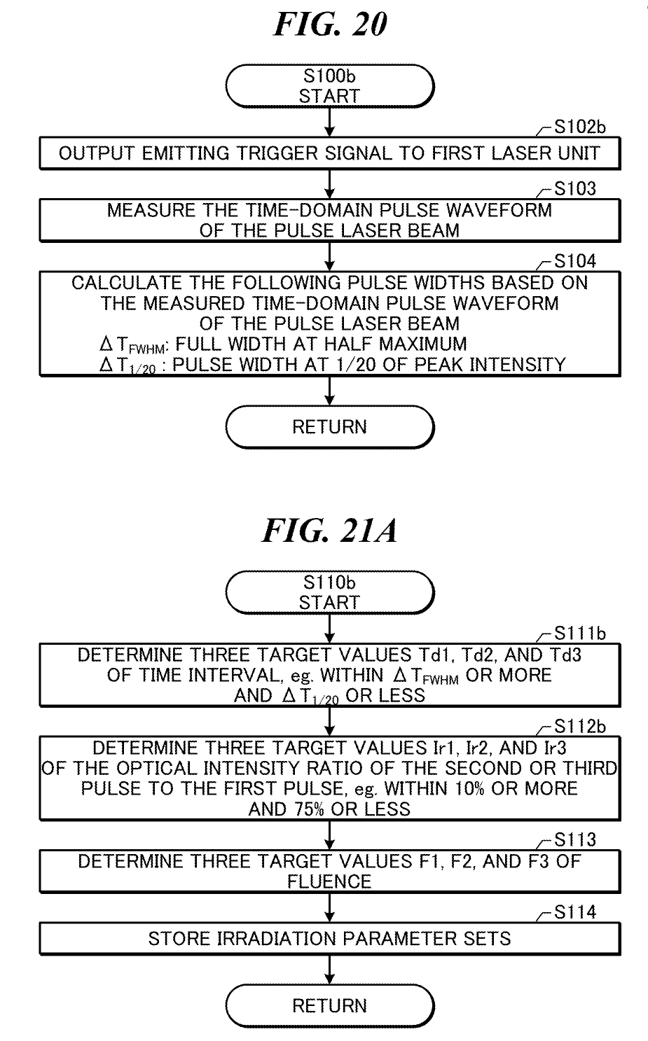

First, in S100b, the annealing controller 45 may measure the time-domain pulse waveform of the pulse laser beam outputted from a single laser unit, and calculate a pulse width of the pulse laser beam. Details of this process will be described later with reference to FIG. 20.

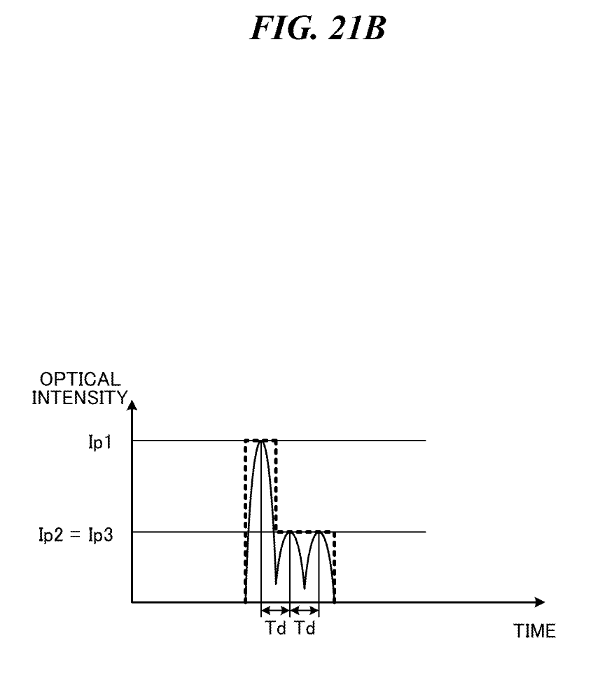

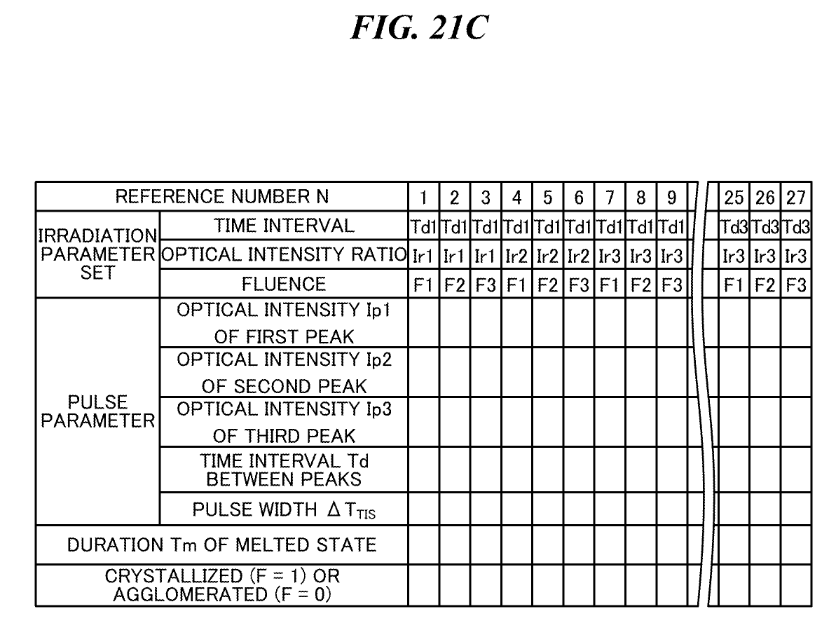

Then, in S110b, the annealing controller 45 may generate irradiation parameter sets having reference number N=1 to reference number N=nmax and store the parameter sets in a memory. The memory will be described later with reference to FIG. 25. The irradiation parameter sets may include nmax number of combinations of a target value of the time interval between each adjacent two of the pulse laser beams outputted from the first, second, and third laser units 2a, 2b, and 2c, a target value of the optical intensity ratio between each adjacent two of the pulse laser beams outputted from the first, second, and third laser units 2a, 2b, and 2c, and a target value of the fluence of the pulse laser beam on the workpiece 43e. Details of this process will be described later with reference to FIGS. 21A and 21B. The irradiation parameter sets may be stored in a data table format to be described with reference to FIG. 21C.

Each of the irradiation parameter sets may include parameters for generating the time-domain pulse waveform and the target value of the fluence on the workpiece 43e. The parameters for generating the time-domain pulse waveform may include the target value of the time interval between each adjacent two of the pulse laser beams outputted from the first, second, and third laser units 2a, 2b, and 2c and the target value of the optical intensity ratio between each adjacent two of the pulse laser beams outputted from the first, second, and third laser units 2a, 2b, and 2c.

S120 and later processes may be similar to those in the first to third embodiments.

The laser system controller 31 may set data on the target pulse energy of each of the first, second, and third laser units 2a, 2b, and 2c based on the target value of the optical intensity ratio between each adjacent two of the pulse laser beams set by the annealing controller 45. The charging voltage with which the charger 12 charges the charging capacitor C0 in each laser unit may be set such that the pulse energy of the pulse laser beam outputted from each laser unit comes close to the target pulse energy. By setting the charging voltage in this manner, the optical intensity ratio between each adjacent two of the pulse laser beams outputted from the laser units may come close to the target value of the optical intensity ratio.

The laser system controller 31 may set the delay time setting data for each of the first, second, and third laser units 2a, 2b, and 2c based on the target value of the time interval between each adjacent two of the pulse laser beams set by the annealing controller 45. The delay times may be set such that the time interval between each adjacent two of the pulse laser beams outputted from the first, second, and third laser units 2a, 2b, and 2c comes close to the target value.

### 6.2.2 Details of S100b

FIG. 20 is a flowchart showing details of the process shown in FIG. 19 to calculate the pulse width of the pulse laser beam outputted from the single laser unit. The annealing controller 45 may perform the process shown in FIG. 20 as a subroutine of S100b shown in FIG. 19.

First, in S102b, the annealing controller 45 may output, to the laser system controller 31, an emitting trigger signal to be outputted to the first laser unit 2a.

Then, in S103, the annealing controller 45 may measure the time-domain pulse waveform of the pulse laser beam using the time-domain pulse waveform measuring unit 19.

Then, in S104, the annealing controller 45 may calculate the following pulse widths based on the measured time-domain pulse waveform of the pulse laser beam.

ΔT_{FWHM}: full width at half maximum

ΔT_{1/20}: full width

These pulse widths may be similar to those in the first embodiment.

After S104, the annealing controller 45 may end the process of this flowchart.

### 6.2.3 Details of S110b

FIG. 21A is a flowchart showing details of the process shown in FIG. 19 to generate the irradiation parameter sets. The annealing controller 45 may perform the process shown in FIG. 21A as a subroutine of S110b shown in FIG. 19.

First, in S111b, the annealing controller 45 may determine three target values Td1, Td2, and Td3 of the time interval between each adjacent two of the pulse laser beams outputted from the first, second, and third laser units 2a, 2b, and 2c. The target values of the time interval may be determined so as to fall within ΔT_{FWHM} or more and ΔT_{1/20} or less.

Then, in S112b, the annealing controller 45 may determine three target values Ir1, Ir2, and Ir3 of the optical intensity ratio of the peak intensity of the pulse laser beam outputted from the second laser unit 2b or third laser unit 2c to the peak intensity of the pulse laser beam outputted from the first laser unit 2a. The target values of the optical intensity ratio may be determined so as to fall within a range of 10% or more and 75% or less.

FIG. 21B shows an example of the time-domain pulse waveform of the pulse laser beam outputted from the laser system 3b. The pulse laser beams outputted from the first, second, and third laser units 2a, 2b, and 2c at a time interval Td may form a pulse laser beam having a waveform as shown in FIG. 21B and may be outputted from the laser system 3b.

The second pulse laser beam outputted from the second laser unit 2b may have a delay time corresponding to the time interval Td with respect to the first pulse laser beam outputted from the first laser unit 2a. Similarly, the third pulse laser beam outputted from the third laser unit 2c may have a delay time corresponding to the time interval Td with respect to the second pulse laser beam outputted from the second laser unit 2b.

An optical intensity Ip2 of a second peak formed by the second pulse laser beam outputted from the second laser unit 2b may have an optical intensity ratio Ir with respect to an optical intensity Ip1 of a first peak formed by the first pulse laser beam outputted from the first laser unit 2a.

Similarly, an optical intensity Ip3 of a third peak formed by the third pulse laser beam outputted from the third laser unit 2c may have the optical intensity ratio Ir with respect to the optical intensity Ip1 of the first peak formed by the first pulse laser beam outputted from the first laser unit 2a.

As seen above, the optical intensity Ip2 of the second peak and the optical intensity Ip3 of the third peak may be approximately the same.

Referring back to FIG. 21A, in S113, the annealing controller 45 may determine three target values F1, F2, and F3 of the fluence of the pulse laser beam on the workpiece 43e. The target values of the fluence of the pulse laser beam on the workpiece 43e may be determined such that at least a part of the workpiece 43e is melted.

Then, in S114, the annealing controller 45 may store, in the memory, the irradiation parameter sets determined in S111b to S113.

FIG. 21C shows an example of a data structure where the irradiation parameter sets are stored in a table format. If three values are determined with respect to each of the target value of the time interval between each adjacent two of the pulse laser beams outputted from the first, second, and third laser units 2a, 2b, and 2c, the target value of the optical intensity ratio between each adjacent two of the pulse laser beams outputted from the first, second, and third laser units 2a, 2b, and 2c, and the target value of the fluence of the pulse laser beam on the workpiece 43e as described above, 27 irradiation parameter sets may be obtained. A table shown in FIG. 21C may contain irradiation parameter sets having reference number N=1 to reference number N=27.

In S170, measurement results with respect to each of the 27 irradiation parameter sets may be stored in the table shown in FIG. 21C.

Note that the number of irradiation parameter sets need not be 27. The number of irradiation parameter sets may be 2 or more.

After S114, the annealing controller 45 may end the process of this flowchart.

### 6.3 Effect

As seen above, in the fourth embodiment, the delay circuit 5 may set the timings when the respective laser units output pulse laser beams. The optical intensity ratio between each adjacent two of the pulse laser beams outputted from the respective laser units may be set based on the charging voltage with which the charger 12 charges the charging capacitor C0 in each laser unit. The delay circuit 5 and the charger 12 of each laser unit may correspond to a time-domain pulse waveform changing apparatus of the present disclosure. According to the fourth embodiment, it is possible to individually set the timings of the laser beams, which are outputted from the respective laser units, and the optical intensity ratio. Thus, flexibility in obtaining a time-domain pulse waveform of a pulse laser beam by combining pulse laser beams may be improved compared to those of the first to third embodiments.

### 7. Example where Irradiation Parameter Set is Provided from External Apparatus (Fifth Embodiment)

### 7.1 Main Flow

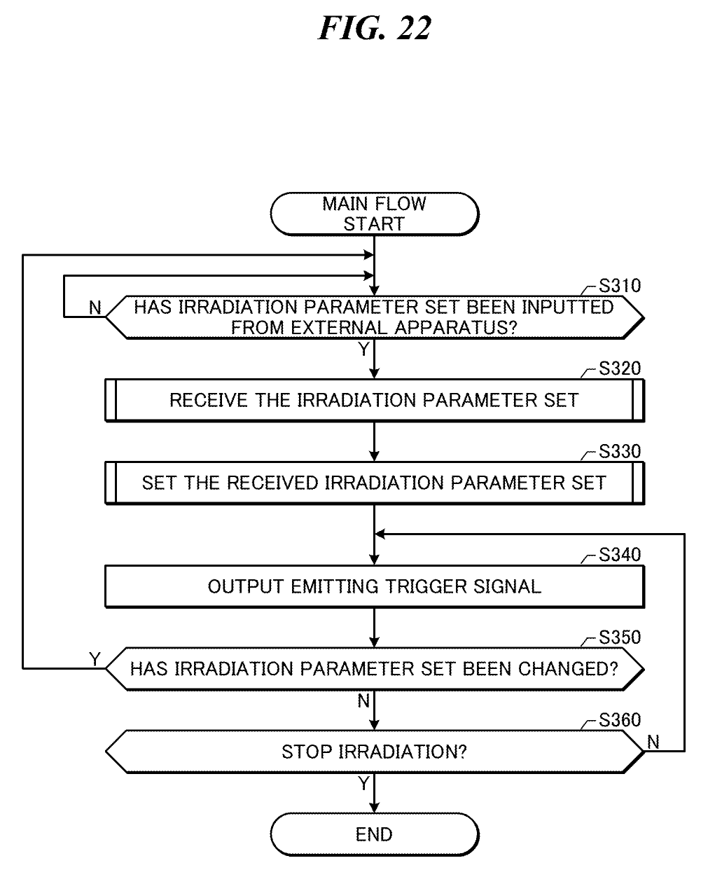

FIG. 22 is a flowchart showing a process to set an irradiation parameter set in a fifth embodiment of the present disclosure. An annealing controller 45 may receive an irradiation parameter set provided from an external apparatus and set them by performing the following process. Accordingly, measurements using a melting state measuring unit 44 are not necessary in this embodiment.

First, in S310, the annealing controller 45 may determine whether an irradiation parameter set has been inputted from the external apparatus. The external apparatus may be, for example, a computer system connected through a network. Alternatively, the external apparatus may be an input apparatus such as a keyboard or a touch-screen display.

If the irradiation parameter set has not been inputted from the external apparatus (S310: NO), the annealing controller 45 may wait until the irradiation parameter set is inputted. If the irradiation parameter set has been inputted from the external apparatus (S310: YES), the annealing controller 45 may proceed to S320.

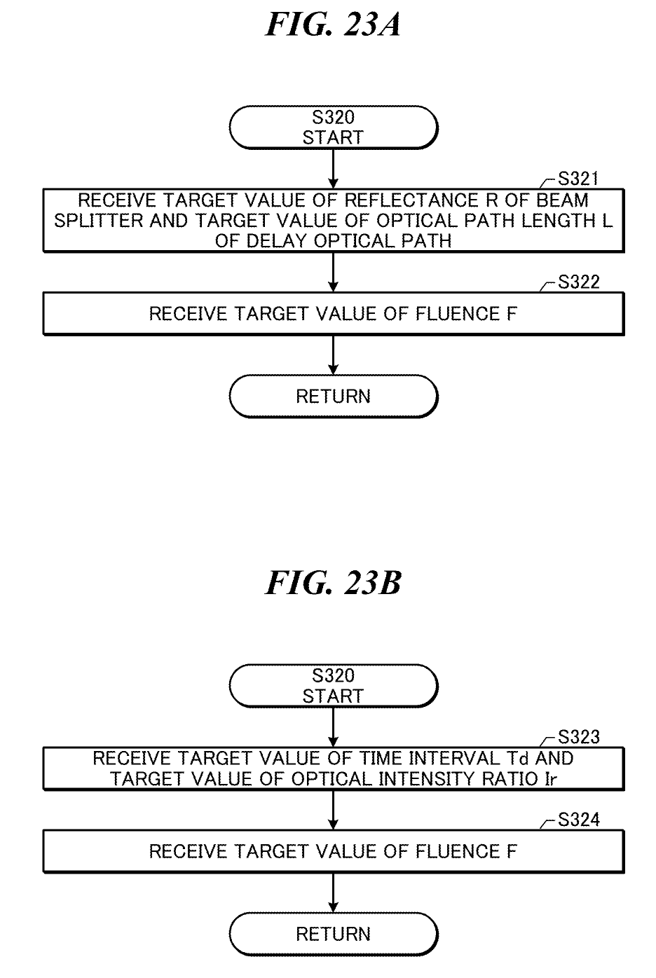

In S320, the annealing controller 45 may receive the inputted irradiation parameter set. This process will be described later with reference to FIGS. 23A and 23B.

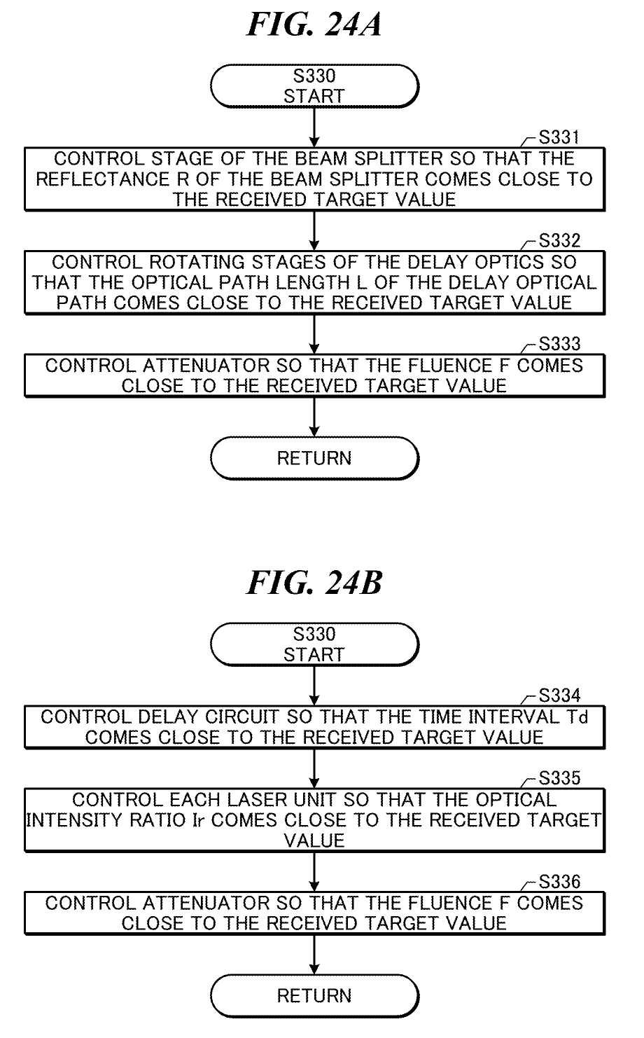

Then, in S330, the annealing controller 45 may set parameters of the received irradiation parameter set to the corresponding apparatuses. This process will be described later with reference to FIGS. 24A and 24B.

Then, in S340, the annealing controller 45 may output the emitting trigger signal to the laser system controller 31. Thus, the workpiece may be irradiated with the pulse laser beam.

Then, in S350, the annealing controller 45 may determine whether the irradiation parameter set has been changed. If the irradiation parameter set has been changed (S350: YES), the annealing controller 45 may return to S310 to receive irradiation parameter set again.

If the irradiation parameter set has not been changed (S350: NO), the annealing controller 45 may proceed to S360. In S360, the annealing controller 45 may determine whether the irradiation with the pulse laser beam should be stopped. If the irradiation with the pulse laser beam should not be stopped (S360: NO), the annealing controller 45 may return to S340 to repeatedly output the emitting trigger signal. If the irradiation with the pulse laser beam should be stopped (S360: YES), the annealing controller 45 may end the process of this flowchart.

### 7.2 Details of S320 (First Example)

FIG. 23A is a flowchart showing a first example of the process shown in FIG. 22 to receive the irradiation parameter set. The annealing controller 45 may perform the process shown in FIG. 23A as a subroutine of S320 shown in FIG. 22. The process shown in FIG. 23A may be performed in the configuration in which the irradiation parameter set is changed by controlling the optical pulse stretcher 16 described in the first or second embodiment.

First, in S321, the annealing controller 45 may receive a target value of the reflectance R of the beam splitter 16n and a target value of the optical path length L of the delay optical path.

Then, in S322, the annealing controller 45 may receive a target value of the fluence F.

After S322, the annealing controller 45 may end the process of this flowchart to proceed to S330 in FIG. 22.

### 7.3 Details of S320 (Second Example)

FIG. 23B is a flowchart showing a second example of the process shown in FIG. 22 to receive the irradiation parameter set. The annealing controller 45 may perform the process shown in FIG. 23B as a subroutine of S320 shown in FIG. 22. The process shown in FIG. 23B may be performed in the configuration in which the irradiation parameter set is changed by controlling the delay circuit 5, and the first, second and third laser units 2a, 2b, and 2c, described in the fourth embodiment.

First, in S323, the annealing controller 45 may receive a target value of the time interval Td and a target value of the optical intensity ratio Ir.

Then, in S324, the annealing controller 45 may receive a target value of the fluence F.

After S324, the annealing controller 45 may end the process of this flowchart to proceed to S330 in FIG. 22.

### 7.4 Details of S330 (First Example)

FIG. 24A is a flowchart showing a first example of the process shown in FIG. 22 to set the received irradiation parameter set. The annealing controller 45 may perform the process shown in FIG. 24A as a subroutine of S330 shown in FIG. 22. Subsequent to the process shown in FIG. 23A, the process shown in FIG. 24A may be performed in the configuration in which the irradiation parameter set is changed by controlling the optical pulse stretcher 16, described in the first or second embodiment.

First, in S331, the annealing controller 45 may control the uniaxial stage 16r or the stepping motor 16x through the laser system controller 31 so that the reflectance R of the beam splitter 16n comes close to the received target value.

Then, in S332, the annealing controller 45 may control the rotating stages 16i, 16j, 16k, and 16m through the laser system controller 31 so that the optical path length L of the delay optical path comes close to the received target value.

Then, in S333, the annealing controller 45 may control the attenuator 18 through the laser system controller 31 so that the fluence F comes close to the received target value.

After S333, the annealing controller 45 may end the process of this flowchart to proceed to S340 in FIG. 22.

### 7.5 Details of S330 (Second Example)

FIG. 24B is a flowchart showing a second example of the process shown in FIG. 22 to set the received irradiation parameter set. The annealing controller 45 may perform the process shown in FIG. 24B as a subroutine of S330 shown in FIG. 22. Subsequent to the process shown in FIG. 23B, the process shown in FIG. 24B may be performed in the configuration in which the irradiation parameter set is changed by controlling the delay circuit 5 and the first to third laser units 2a to 2c, described in the fourth embodiment.

First, in S334, the annealing controller 45 may control the delay circuit 5 through the laser system controller 31 so that the time interval Td comes close to the received target value.

Then, in S335, the annealing controller 45 may control the first to third laser units 2a to 2c through the laser system controller 31 so that the optical intensity ratio Ir comes close to the received target value.

Then, in S336, the annealing controller 45 may control the attenuator 18 through the laser system controller 31 so that the fluence F comes close to the received target value.

After S336, the annealing controller 45 may end the process of this flowchart to proceed to S340 in FIG. 22.

According to the fifth embodiment, even if measurements are not made using the melting state measuring unit 44, irradiation parameter sets may be set by receiving them from the external apparatus.

### 8. Configuration of Controller

FIG. 25 is a block diagram schematically showing a configuration of the controller.

Controllers of the above-described embodiments, such as the annealing controller 45 and the laser system controller 31, may be general-purpose control devices, such as computers or programmable controllers. For example, the controllers may be configured as follows:

### Configuration

The controllers may each include a processor 1000, and a storage memory 1005, a user interface 1010, a parallel input/output (I/O) controller 1020, a serial I/O controller 1030, and an analog-to-digital (A/D) and digital-to-analog (D/A) converter 1040 which are connected to the processor 1000. The processor 1000 may include a central processing unit (CPU) 1001, and a memory 1002, a timer 1003, and a graphics processing unit (GPU) 1004 which are connected to the CPU 1001.

### Operation

The processor 1000 may read a program stored in the storage memory 1005, execute thee read program, read data from the storage memory 1005 in accordance with the program, or store data in the storage memory 1005.

The parallel I/O controller 1020 may be connected to devices 1021 to 102x with which it may communicate through parallel I/O ports. The parallel I/O controller 1020 may control digital-signal communication through the parallel I/O ports while the processor 1000 executes the program.

The serial I/O controller 1030 may be connected to devices 1031 to 103x with which it may communicate through serial I/O ports. The serial I/O controller 1030 may control digital-signal communication through the serial I/O ports while the processor 1000 executes the program.

The A/D and D/A converter 1040 may be connected to devices 1041 to 104x with which it may communicate through analog ports. The A/D and D/A converter 1040 may control analog-signal communication through the analog ports while the processor 1000 executes the program.

The user interface 1010 may be configured to display the progress of the program being executed by the processor 1000 in accordance with instructions from an operator, or to cause the processor 1000 to stop the execution of the program or perform an interrupt in accordance with instructions from the operator.

The CPU 1001 of the processor 1000 may perform arithmetic processing of the program. The memory 1002 may temporarily store the program being executed by the CPU 1001 or temporarily store data in the arithmetic processing. The timer 1003 may measure time or elapsed time and output it to the CPU 1001 in accordance with the program being executed. When image data is inputted to the processor 1000, the GPU 1004 may process the image data in accordance with the program being executed and output the results to the CPU 1001.

The devices 1021 to 102x, which are connected through the parallel I/O ports to the parallel I/O controller 1020, may be used when the laser apparatus 2 or another apparatus such as the controller receives or sends the emitting trigger signal or other time-indicating signal.

The devices 1031 to 103x, which are connected through the serial I/O ports to the serial I/O controller 1030, may be used when the laser apparatus 2, the optical pulse stretcher 16, the attenuator 18, the XYZ stage 43g, any controller, or the like sends or receives data.

The devices 1041 to 104x, which are connected through the analog ports to the A/D and D/A converter 1040, may serve as various sensors, such as the pulse waveform measuring unit 19, the melting state measuring unit 44, and the like.

The controllers thus configured may be capable of realizing the operations described in the embodiments.

The above descriptions are intended to be only illustrative rather than being limiting. Accordingly, it will be clear to those skilled in the art that various changes may be made to the embodiments of the present disclosure without departing from the scope of the appended claims.

The terms used in the present specification and the appended claims are to be interpreted as not being limiting. For example, the term “include” or “included” should be interpreted as not being limited to items described as being included. Further, the term “have” should be interpreted as not being limited to items described as being had. Furthermore, the modifier “a” or “an” as used in the present specification and the appended claims should be interpreted as meaning “at least one” or “one or more”.

1. A laser system serving as a light source of a laser annealing apparatus that irradiates a workpiece with a pulse laser beam, the laser system comprising:
a laser apparatus configured to generate the pulse laser beam;
a time-domain pulse waveform changing apparatus configured to change time-domain pulse waveform of the pulse laser beam; and
a controller configured to receive at least one parameter for generating the time-domain pulse waveform from the laser annealing apparatus and to control the time-domain pulse waveform changing apparatus.

2. The laser system according to claim 1, wherein
the time-domain pulse waveform changing apparatus comprises:
a beam splitter configured to branch the pulse laser beam outputted from the laser apparatus into first and second optical paths;
a reflectance changing unit configured to change a reflectance of the beam splitter reflecting the pulse laser beam;
delay optics having a delay optical path and configured to cause the pulse laser beam traveling the second optical path to enter the beam splitter so that the beam splitter further branches the pulse laser beam into the first and second optical paths; and
an optical path length changing unit configured to change an optical path length of the delay optical path,
the at least one parameter for generating the time-domain pulse waveform includes a target value of the reflectance and a target value of the optical path length, and
the controller controls the reflectance changing unit and the optical path length changing unit so that the reflectance comes close to the target value of the reflectance and that the optical path length comes close to the target value of the optical path length.

3. The laser system according to claim 1, wherein
the laser apparatus comprises:
a first laser unit configured to output a first pulse laser beam; and
a second laser unit configured to output a second pulse laser beam,
the time-domain pulse waveform changing apparatus comprises:
a delay circuit configured to change a time interval between the first pulse laser beam outputted from the first laser unit and the second pulse laser beam outputted from the second laser unit,
a first charger included in the first laser unit and a second charger included in the second laser unit, the first and second chargers each being configured to change charging voltage of a corresponding charging capacitor in order to change an optical intensity ratio between the first pulse laser beam and the second pulse laser beam,
the at least one parameter for generating the time-domain pulse waveform includes a target value of the time interval between the first and second pulse laser beams and a target value of the optical intensity ratio between the first and second pulse laser beams, and
the controller controls the delay circuit and the first and second chargers so that the time interval comes close to the target value of the time interval and that the optical intensity ratio comes close to the target value of the optical intensity ratio.

4. A laser annealing apparatus for irradiating a workpiece with a pulse laser beam, comprising:
a laser apparatus configured to generate the pulse laser beam;
a time-domain pulse waveform changing apparatus configured to change time-domain pulse waveform of the pulse laser beam;
optics configured to irradiate the workpiece with the pulse laser beam;
a fluence changing unit configured to change fluence of the pulse laser beam on the workpiece; and
a controller configured to control the time-domain pulse waveform changing apparatus and the fluence changing unit based on an irradiation parameter set including at least one parameter for generating the time-domain pulse waveform and a target value of the fluence of the pulse laser beam on the workpiece.

5. The laser annealing apparatus according to claim 4, wherein
the laser annealing apparatus receives the irradiation parameter set from an external apparatus, and
the controller controls the time-domain pulse waveform changing apparatus and the fluence changing unit based on the received irradiation parameter set.

6. The laser annealing apparatus according to claim 4, wherein
the time-domain pulse waveform changing apparatus comprises:
a beam splitter configured to branch the pulse laser beam outputted from the laser apparatus into first and second optical paths;
a reflectance changing unit configured to change a reflectance of the beam splitter reflecting the pulse laser beam;
delay optics having a delay optical path and configured to cause the pulse laser beam traveling the second optical path to enter the beam splitter so that the beam splitter further branches the pulse laser beam into the first and second optical paths; and
an optical path length changing unit configured to change an optical path length of the delay optical path,
the at least one parameter for generating the time-domain pulse waveform includes a target value of the reflectance and a target value of the optical path length, and
the controller controls the reflectance changing unit and the optical path length changing unit so that the reflectance comes close to the target value of the reflectance and that the optical path length comes close to the target value of the optical path length.

7. The laser annealing apparatus according to claim 4, wherein
the laser apparatus comprises:
a first laser unit configured to output a first pulse laser beam; and
a second laser unit configured to output a second pulse laser beam,
the time-domain pulse waveform changing apparatus comprises:
a delay circuit configured to change a time interval between the first pulse laser beam outputted from the first laser unit and the second pulse laser beam outputted from the second laser unit,
a first charger included in the first laser unit and a second charger included in the second laser unit, the first and second chargers each being configured to change charging voltage of a corresponding charging capacitor in order to change an optical intensity ratio between the first pulse laser beam and the second pulse laser beam,
the at least one parameter for generating the time-domain pulse waveform includes a target value of the time interval between the first and second pulse laser beams and a target value of the optical intensity ratio between the first and second pulse laser beams, and
the controller controls the delay circuit and the first and second chargers so that the time interval comes close to the target value of the time interval and that the optical intensity ratio comes close to the target value of the optical intensity ratio.

8. The laser annealing apparatus according to claim 4, further comprising a measuring unit for measuring a duration of a melted state that is a time period during which the melted state of at least a part of the workpiece continues and measure a status of crystallization after expiration of the duration of the melted state.

9. The laser annealing apparatus according to claim 8, wherein the controller
acquires measurement results made by the measuring unit for each of irradiation parameter sets and
selects, from the irradiation parameter sets, an irradiation parameter set that meets a first condition that the status of crystallization measured by the measuring unit indicates that at least a part of the workpiece has crystallized, and meets a second condition that the longest duration of the melted state has been measured by the measuring unit in the irradiation parameter sets that meet the first condition.

10. The laser annealing apparatus according to claim 9, wherein the controller
acquires irradiation parameter sets each including
a parameter for generating the time-domain pulse waveform that is identical to a parameter for generating the time-domain pulse waveform included in the selected irradiation parameter set and
a target value of the fluence that is different from a target value of the fluence included in the selected irradiation parameter set,
obtains a curve showing a relationship between the duration of the melted state measured by the measuring unit and the fluence for the acquired irradiation parameter sets, and
selects a value of the fluence where the curve leaves an approximate straight line showing the relation.

11. The laser annealing apparatus according to claim 4, wherein the fluence changing unit includes an attenuator configured to change a transmittance of the attenuator transmitting the pulse laser beam.

12. The laser annealing apparatus according to claim 7, further comprising a beam homogenizer including a fly-eye lens and condenser optics, wherein
the beam homogenizer is configured to combine the first and second pulse laser beams.
